(19) United States
(12) Patent Application Publication
(10) Pub. No.: US 2025/0366350 A1
(43) Pub. Date: Nov. 27, 2025

(54) DISPLAY DEVICE AND ELECTRONIC DEVICE INCLUDING THE SAME

(71) Applicant: Samsung Display Co., LTD., Yongin-si (KR)

(72) Inventors: WOO YONG SUNG, Yongin-si (KR); SEUNGYONG SONG, Yongin-si (KR); HEE JUN YANG, Yongin-si (KR); JEONGSEOK LEE, Yongin-si (KR)

(21) Appl. No.: 19/057,088

(22) Filed: Feb. 19, 2025

(30) Foreign Application Priority Data
May 21, 2024 (KR) 10-2024-0065717

(51) Int. Cl. H10K 59/80; H10K 59/122

(52) U.S. Cl. CPC H10K 59/873; H10K 59/122

(57) ABSTRACT

A display device includes: a pixel electrode disposed on a substrate, a pixel defining layer disposed on the pixel electrode and defining a pixel opening exposing a least a portion of an upper surface of the pixel electrode, a side wall disposed directly on the pixel defining layer and having an undercut structure, a light emitting layer disposed on the side wall, disposed inside the pixel opening, and disconnected by the undercut structure, a first inorganic encapsulation layer disposed on the light emitting layer and directly contact a side surface of the side wall, an organic encapsulation layer disposed on the first inorganic encapsulation layer, and a second inorganic encapsulation layer disposed on the organic encapsulation layer.

This application claims priority to Korean Patent Application No. 10-2024-0065717, filed on May 21, 2024, and all the benefits accruing therefrom under 35 U.S.C. § 119, the content of which in its entirety is herein incorporated by reference.

### BACKGROUND

### 1. Field

Embodiments provide generally to a display device. More particularly, embodiments relate to a flexible display device.

### 2. Description of the Related Art

As information technology develops, the importance of display devices, which are communication media between users and information, is being highlighted. Accordingly, display devices such as a liquid crystal display device, an organic light emitting display device, a plasma display device, and the like are widely used in various fields.

In flexible display device, since a light emitting element include therein are generally vulnerable to moisture, oxygen, and the like, a thin film encapsulation layer in which at least one inorganic layer and at least one organic layer are alternately stacked is formed on the light emitting element.

### SUMMARY

Embodiments provide a display device with improved flexibility.

Embodiments provide an electronic device including the display device.

A display device according to embodiments of the disclosure includes a pixel electrode disposed on a substrate, a pixel defining layer disposed on the pixel electrode and defining a pixel opening exposing a least a portion of an upper surface of the pixel electrode, a side wall disposed directly on the pixel defining layer and having an undercut structure, a light emitting layer disposed on the side wall, disposed inside the pixel opening, and disconnected by the undercut structure, a first inorganic encapsulation layer disposed on the light emitting layer and directly contact a side surface of the side wall, an organic encapsulation layer disposed on the first inorganic encapsulation layer, and a second inorganic encapsulation layer disposed on the organic encapsulation layer.

In an embodiment, a surface area of the first inorganic encapsulation layer may be different from a surface area of the second inorganic encapsulation layer.

In an embodiment, the surface area of the first inorganic encapsulation layer may be greater than the surface area of the second inorganic encapsulation layer.

In an embodiment, the side wall may include a first sub-layer disposed on the pixel defining layer and including a conductive material and a second sub-layer disposed on the first sub-layer, including a conductive material or an inorganic material, and having a second side surface protruding more toward a center of the pixel opening than a first side surface of the first sub-layer in a plan view.

In an embodiment, the first sub-layer may include aluminum (Al) and the second sub-layer may include titanium (Ti).

In an embodiment, a first angle between a side surface of the pixel defining layer and a lower surface of the pixel defining layer may be in a range from about 40 degrees to about 90 degrees.

In an embodiment, a second angle between a side surface of the first sub-layer and a lower surface of the first sub-layer may be different from the first angle.

In an embodiment, the second angle may be greater than the first angle.

In an embodiment, a second angle between a side surface of the first sub-layer and a lower surface of the first sub-layer may be in a range from about 70 degrees to about 90 degrees.

In an embodiment, a thickness of a portion of the first inorganic encapsulation layer contacting a lower surface of a protruding portion of the second sub-layer may range from less than about 0.3 micrometer (μm).

In an embodiment, a height of the first sub-layer may be in a range from about 1 to about 2 times a length of a protruding portion of the second sub-layer in a horizontal direction.

In an embodiment, an average thickness of the first inorganic encapsulation layer may be different from a thickness of the second inorganic encapsulation layer.

In an embodiment, the display device may further include a common electrode disposed between the light emitting layer and the first inorganic encapsulation layer, and disconnected by the undercut structure.

In an embodiment, the common electrode may directly contact an upper surface of the light emitting layer and at least a portion of the side surface of the side wall.

In an embodiment, the display device may further include a pixel protective layer disposed directly on the pixel electrode, exposing at least a portion of the pixel electrode, and including a conductive metal oxide.

In an embodiment, the pixel defining layer may include an inorganic material.

A display device according to embodiments of the disclosure includes a substrate including a first pixel area which emits light of a first color, a second pixel area which emits light of a second color different from the first color, and a third pixel area which emits light of a third color different from the first and second colors, first, second, and third pixel electrodes respectively disposed in the first, second, and third pixel areas on the substrate, a pixel defining layer disposed on the first, second, and third pixel electrodes and defining first, second, and third pixel openings exposing a least a portion of upper surfaces of the first, second, and third pixel electrode, respectively, a side wall disposed directly on the pixel defining layer and having an undercut structure, first, second, and third light emitting layers disposed on the side wall, and disposed inside the first, second, and third pixel openings, respectively, where each of the first, second, and third light emitting layers is disconnected by the undercut structure a first first inorganic encapsulation layer disposed on the first light emitting layer and directly contacting a side surface of the side wall in the first pixel area, a second first inorganic encapsulation layer disposed on the second light emitting layer and directly contacting a side surface of the side wall in the second pixel area, a third first inorganic encapsulation layer disposed on the third light emitting layer and directly contacting a side surface of the side wall in the third pixel area, an organic encapsulation layer disposed on the first first, second first, and third first inorganic encapsulation layers, and a second inorganic encapsulation layer disposed on the organic encapsulation layer.

In an embodiment, a surface area of the first first inorganic encapsulation layer may be greater than a surface area of a portion of the second inorganic encapsulation layer in the first pixel area, a surface area of the second first inorganic encapsulation layer may be greater than a surface area of a portion of the second inorganic encapsulation layer in the second pixel area, and a surface area of the third first inorganic encapsulation layer may be greater than a surface area of a portion of the second inorganic encapsulation layer in the third pixel area.

In an embodiment, the first first inorganic encapsulation layer, the second first inorganic encapsulation layer, and the third first inorganic encapsulation layer may be spaced part from each other.

In an embodiment, the side wall may include a first sub-layer disposed on the pixel defining layer and including a conductive material and a second sub-layer disposed on the first sub-layer, including a conductive material or an inorganic material, and having a second side surface protruding more toward a center of each of the first, second, and third pixel openings than a first side surface of the first sub-layer in a plan view.

In an embodiment, the first sub-layer may include aluminum (Al) and the second sub-layer may include titanium (Ti).

In an embodiment, a first angle between a side surface of the pixel defining layer and a lower surface of the pixel defining layer may be in a range from about 40 degrees to about 90 degrees.

In an embodiment, a second angle between a side surface of the first sub-layer and a lower surface of the first sub-layer may be greater than the first angle.

In an embodiment, a second angle between a side surface of the first sub-layer and a lower surface of the first sub-layer may be in a range from about 70 degrees to about 90 degrees.

In an embodiment, a thickness of each of a portion of the first first inorganic encapsulation layer, a portion of the second first encapsulation layer, and a portion of the third first encapsulation layer contacting a lower surface of a protruding portion of the second sub-layer may be less than about 0.3 micrometer (μm).

In an embodiment, a height of the first sub-layer may be in a range from about 1 to about 2 times a length of a protruding portion of the second sub-layer in a horizontal direction.

In an embodiment, an average thickness of each of the first first, second first, and third first inorganic encapsulation layers may be different from a thickness of the second inorganic encapsulation layer.

In an embodiment, the display device may further include a first common electrode disposed between the first light emitting layer and the first first inorganic encapsulation layer, disconnected by the undercut structure, and directly contacting an upper surface of the first emitting layer and at least a portion of the side surface of the side wall in the first pixel area, a second common electrode disposed between the second light emitting layer and the second first inorganic encapsulation layer, disconnected by the undercut structure, and directly contacting an upper surface of the second emitting layer and at least a portion of the side surface of the side wall in the second pixel area, and a third common electrode disposed between the third light emitting layer and the third first inorganic encapsulation layer, disconnected by the undercut structure, and directly contacting an upper surface of the third emitting layer and at least a portion of the side surface of the side wall in the third pixel area.

An electronic device according to embodiments of the disclosure may include a display device and a processor which controls the display device, the display device includes: a pixel electrode disposed on a substrate, a pixel defining layer disposed on the pixel electrode and defining a pixel opening exposing a least a portion of an upper surface of the pixel electrode, a side wall disposed directly on the pixel defining layer and having an undercut structure, a light emitting layer disposed on the side wall, disposed inside the pixel opening, and disconnected by the undercut structure, a first inorganic encapsulation layer disposed on the light emitting layer and directly contact a side surface of the side wall, an organic encapsulation layer disposed on the first inorganic encapsulation layer, and a second inorganic encapsulation layer disposed on the organic encapsulation layer.

A display device according to embodiments of the disclosure may include a pixel electrode disposed on a substrate, a pixel defining layer defining a pixel opening exposing a least a portion of an upper surface of the pixel electrode, a side wall disposed directly on the pixel defining layer and having an undercut structure, a light emitting layer disconnected by the undercut structure on the side wall, a common electrode disconnected by the undercut structure on the light emitting layer, and a first inorganic encapsulation layer disposed on the common electrode and directly contact a side surface of the side wall. In such embodiments, a surface area of the first inorganic encapsulation layer may greater than a surface area of a second inorganic encapsulation layer disposed on an organic encapsulation layer.

In such embodiments, each of a first angle between a side surface of the pixel defining layer and a lower surface of the pixel defining layer, a second angle between a side surface of a first sub-layer of the side wall and a lower surface of the first sub-layer, a thickness of a portion of the first inorganic encapsulation layer contacting a lower surface of a protruding portion of a second sub-layer of the side wall, and a ratio of a height of the first sub-layer to a length of the protruding portion of a second sub-layer in a horizontal direction may have a predetermined value. Accordingly, the flexibility of the display device may be improved.

### BRIEF DESCRIPTION OF THE DRAWINGS

Illustrative, non-limiting embodiments will be more clearly understood from the following detailed description in conjunction with the accompanying drawings.

FIG. 1 is a plan view showing a display device according to an embodiment of the disclosure.

FIG. 2 is a cross-sectional view taken along line I-I′ of FIG. 1.

FIG. 3 is an enlarged cross-sectional view of area A of FIG. 2.

FIGS. 4 to 25 are cross-sectional views showing processes of an embodiment of a method of manufacturing the display device of FIG. 2.

FIG. 26 is a block diagram showing an electronic device according to embodiments of the present disclosure.

FIG. 27 are schematic diagrams showing an electronic device according to various embodiments.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the disclosure will be described in detail with reference to the accompanying drawings. The same reference numerals are used for the same components in the drawings, and any repetitive detailed descriptions of the same components will be omitted or simplified.

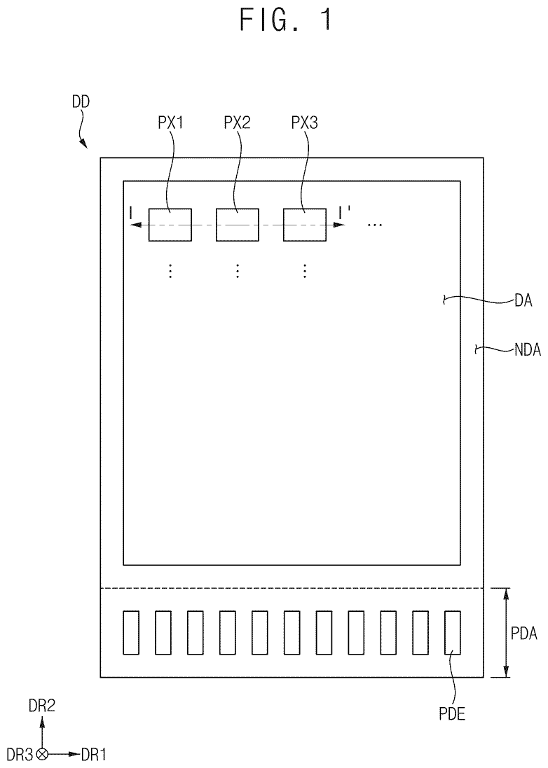

FIG. 1 is a plan view showing a display device according to an embodiment of the disclosure.

Referring to FIG. 1, the display device DD according to an embodiment of the disclosure may include a display area DA and a non-display area NDA. The display area DA may be an area that can display an image by generating light or adjusting the transmittance of light provided from an external light source. The non-display area NDA may be an area that does not display images. The non-display area NDA may be located around the display area DA. In an embodiment, for example, the non-display area NDA may entirely surround the display area DA.

The display area DA may include a plurality of pixel areas. The pixel areas may be arranged in a matrix form along a first direction DR1 and a second direction DR2 crossing the first direction DR1. Here, a third direction DR3 perpendicular to the first direction DR1 and the second direction DR2 may be a thickness direction of the display device DD. In an embodiment, for example, the pixel areas may include a first pixel area PX1, a second pixel area PX2, and a third pixel area PX3.

Each of the first pixel area PX1, the second pixel area PX2, and the third pixel area PX3 may be defined by an area where light emitted from a light emitting element is emitted to the outside of the display device DD. In an embodiment, for example, the first pixel area PX1 may emit light of a first color, the second pixel area PX2 may emit light of a second color, and the third pixel area PX3 may emit light of a third color. In an embodiment, the first color may be red, the second color may be green, and the third color may be blue. However, embodiments of the disclosure are not necessarily limited thereto. In another embodiment, for example, the first, second, and third pixel areas PX1, PX2, and PX3 may be combined to emit yellow, cyan, and magenta lights.

The first, second, and third pixel areas PX1, PX2, and PX3 may emit light of four or more colors. In an embodiment, for example, the first, second, and third pixel areas PX1, PX2, and PX3 may be combined to emit at least one selected from yellow, cyan, and magenta lights in addition to red, green, and blue lights. In addition, the first, second, and third pixel areas PX1, PX2, and PX3 may be combined to emit more white light.

Each of the first pixel area PX1, the second pixel area PX2, and the third pixel area PX3 may have a triangular planar shape, a square planar shape, a circular planar shape, an oval planar shape, or the like in a plan view or when viewed in the third direction DR3. In an embodiment, each of the first pixel area PX1, the second pixel area PX2, and the third pixel area PX3 may have a rectangular planar shape. However, embodiments of the disclosure are not necessarily limited, and the first pixel area PX1, the second pixel area PX2, and the third pixel area PX3 may have different planar shapes from each other.

The non-display area NDA may include a pad area PDA. The pad area PDA may be located away from one side of the display area DA. In an embodiment, for example, the pad area PDA may have a shape extending in the first direction DR1.

A plurality of lines may be disposed in the non-display area NDA, and a plurality of pad electrodes PDE may be disposed in the pad area PDA. The lines may electrically connect pad electrodes PDE and the pixel areas. In an embodiment, for example, the lines may include data signal lines, scan signal lines, light emitting control signal lines, power voltage lines, or the like.

The pad electrodes PDE may be disposed to be spaced apart from each other in the first direction DR1. In an embodiment, for example, each of the pad electrodes PDE may include metal, alloy, metal nitride, conductive metal oxide, transparent conductive material, or the like. These can be used alone or in combination with each other.

In this specification, a plane may be defined as the first direction DR1 and the second direction DR2 that intersects the first direction DR1. For example, the first direction DR1 and the second direction DR2 may be perpendicular to each other. In addition, the third direction DR3 may be perpendicular to the plane.

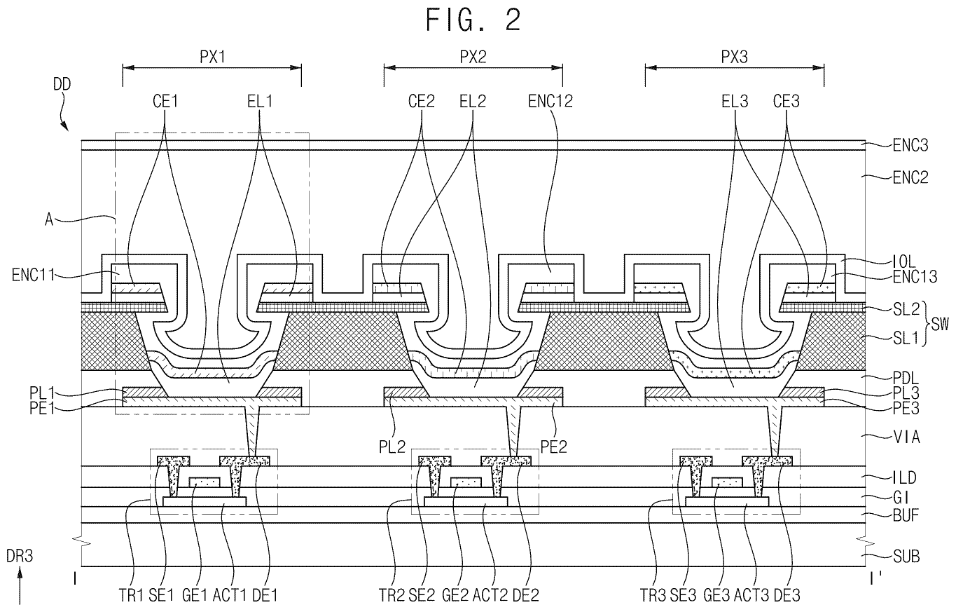

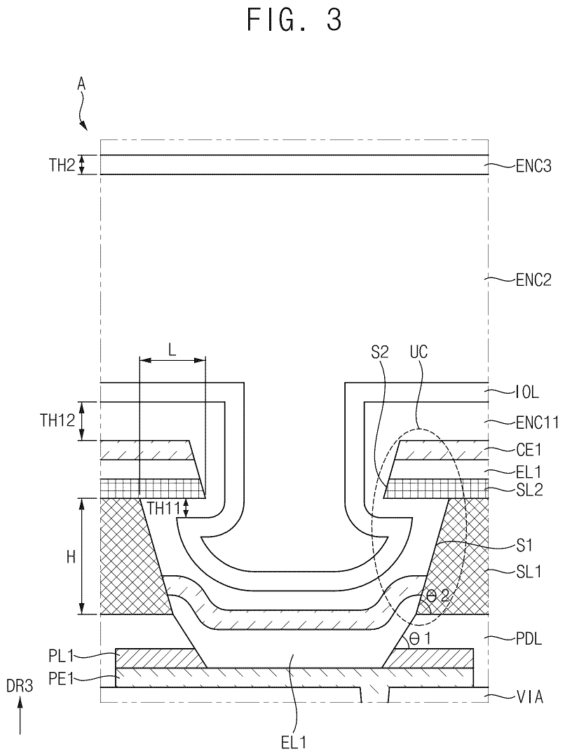

FIG. 2 is a cross-sectional view taken along line I-I′ of FIG. 1. FIG. 3 is an enlarged cross-sectional view of area A of FIG. 2.

Referring to FIGS. 2 and 3, the display device DD according to an embodiment of the disclosure may include a substrate SUB, a buffer layer BUF, first, second, and third transistors TR1, TR2, and TR3, a gate insulation layer GI, an interlayer insulating layer ILD, a via insulating layer VIA, first, second, and third pixel electrodes PE1, PE2, and PE3, first, second, and third pixel protective layers PL1, PL2, and PL3, a pixel defining layer PDL, a side wall SW, first, second, and third light emitting layers EL1, EL2, and EL3, first, second, and third common electrodes CE1, CE2, and CE3, first first, second first, and third first inorganic encapsulation layers ENC11, ENC12, and ENC13, an inorganic insulating layer IOL, an organic encapsulation layer ENC2, and a second inorganic encapsulation layer ENC3.

In an embodiment, the first transistor TR1 may include a first active pattern ACT1, a first gate electrode GE1, a first source electrode SE1, and a first drain electrode DE1, the second transistor TR2 may include a second active pattern ACT2, a second gate electrode GE2, a second source electrode SE2, and a second drain electrode DE2, and the third transistor TR3 may include a third active pattern ACT3, a third gate electrode GE3, a third source electrode SE3, and a third drain electrode DE3.

FIG. 3 shows the first light emitting layer EL1, the first common electrode CE1, and the first first inorganic encapsulation layer ENC11 of FIG. 2 in detail. The structure, the shape and the position of the second and third light emitting layers EL2 and EL3, the second and third common electrodes CE2 and CE3, and the second first and third first inorganic encapsulation layers ENC12 and ENC13 of FIG. 2 may be substantially the same as the first light emitting layer EL1, the first common electrode CE1, and the first first inorganic encapsulation layer ENC11 of FIG. 3, respectively.

The substrate SUB may include a transparent material or an opaque material. The substrate SUB may include or be made of a transparent resin substrate. Examples of the transparent resin substrate may include a polyimide substrate. In this case, the polyimide substrate may include a first organic layer, a first barrier layer, a second organic layer, or the like. Alternatively, the substrate SUB may include a quartz substrate, synthetic quartz substrate, calcium fluoride substrate, F-doped quartz substrate, a soda-lime glass substrate, a non-alkali glass substrate, or the like. These can be used alone or in combination with each other. Alternatively, the substrate SUB may include a silicon wafer. Here, the third direction DR3 may be a thickness direction of the substrate SUB.

The buffer layer BUF may be disposed on the substrate SUB. The buffer layer BUF may effectively prevent metal atoms or impurities from diffusing from the substrate SUB to the first, second, and third transistors TR1, TR2, and TR3. In addition, the buffer layer BUF may improve the flatness of the surface of the substrate SUB when the surface of the substrate SUB is not uniform. In an embodiment, for example, the buffer layer BUF may include an inorganic material such as silicon oxide, silicon nitride, silicon oxynitride, or the like. These can be used alone or in combination.

The first, second, and third active patterns ACT1, ACT2, and ACT3 may be disposed on the buffer layer BUF. Each of the first, second, and third active patterns ACT1, ACT2, and ACT3 may include a metal oxide semiconductor, an inorganic semiconductor (e.g., amorphous silicon, poly silicon), or an organic semiconductor. Each of the first, second, and third active patterns ACT1, ACT2, and ACT3 may include a source region, a drain region, and a channel region located between the source region and the drain region. The first, second, and third active patterns ACT1, ACT2, and ACT3 may formed through a same process as each other and may include a same material as each other.

The metal oxide semiconductor may include indium (In), zinc (Zn), gallium (Ga), tin (Sn), titanium (Ti), aluminum (Al), hafnium (Hf), zirconium (Zr), magnesium (Mg), or the like containing a binary compound (ABₓ), a ternary compound (ABₓC_{y}), a quaternary component compound (ABₓC_{y}D_{z}), or the like. In an embodiment, for example, the metal oxide semiconductor may include zinc oxide (ZnOₓ), gallium oxide (GaOₓ), tin oxide (SnOₓ), indium oxide (InOₓ), indium gallium oxide (IGO), indium zinc oxide (IZO), indium tin oxide (ITO), indium zinc tin oxide (IZTO), indium gallium zinc oxide (IGZO), or the like. These can be used alone or in combination with each other.

The gate insulating layer GI may be disposed on the buffer layer BUF. The gate insulating layer GI may sufficiently cover the first, second, and third active patterns ACT1, ACT2, and ACT3, and may have a substantially flat upper surface without creating or defining steps (stepped structures) around the first, second, and third active patterns ACT1, ACT2, and ACT3. Alternatively, the gate insulating layer GI may cover the first, second, and third active patterns ACT1, ACT2, and ACT3, and may be disposed along the profile of each of the first, second, and third active patterns ACT1, ACT2, and ACT3 with a uniform (or substantially constant) thickness. In an embodiment, for example, the gate insulating layer GI may include an inorganic material such as silicon oxide (SiOₓ), silicon nitride (SiNₓ), silicon carbide (SiCₓ), silicon oxynitride (SiOₓN_{y}), silicon oxycarbide (SiOₓC_{y}), or the like. These can be used alone or in combination with each other.

The first, second, and third gate electrodes GE1, GE2, and GE3 may be disposed on the gate insulating layer GI. The first gate electrode GE1 may overlap the channel area of the first active pattern ACT1, the second gate electrode GE2 may overlap the channel area of the second active pattern ACT2, and the third gate electrode GE3 may overlap the channel area of the third active pattern ACT3 in a plan view (or in the third direction DR3).

Each of the first, second, and third gate electrodes GE1, GE2, and GE3 may include metal, alloy metal nitride, conductive metal oxide, transparent conductive material, or the like. Examples of the metal may include silver (Ag), molybdenum (Mo), aluminum (Al), tungsten (W), copper (Cu), nickel (Ni), chromium (Cr), titanium (Ti), tantalum (Ta), platinum (Pt), scandium (Sc), or the like. Examples of the conductive metal oxide may include indium tin oxide, indium zinc oxide, or the like. In addition, examples of the metal nitride may include aluminum nitride (AlNₓ), tungsten nitride (WNₓ), chromium nitride (CrNₓ), or the like. These can be used alone or in combination with each other.

The first, second, and third gate electrodes GE1, GE2, and GE3 may formed through a same process as each other and may include a same material as each other.

The interlayer insulating layer ILD may be disposed on the gate insulating layer GI. The interlayer insulating layer ILD may sufficiently cover the first, second, and third gate electrodes GE1, GE2, and GE3, and may have a substantially flat upper surface without creating steps around the first, second, and third gate electrodes GE1, GE2, and GE3. Alternatively, the interlayer insulating layer ILD may cover the first, second, and third gate electrodes GE1, GE2, and GE3, and may be disposed along the profile of each of the first, second, and third gate electrodes GE1, GE2, and GE3 with a uniform thickness. In an embodiment, for example, the interlayer dielectric layer ILD may include an inorganic material such as silicon oxide, silicon nitride, silicon carbide, silicon oxynitride, silicon oxycarbide, or the like. These can be used alone or in combination with each other.

The first, second, and third source electrodes SE1, SE2, and SE3 may be disposed on the interlayer insulating layer ILD. The first source electrode SE1 may be connected to the source region of the first active pattern ACT1 through a contact hole defined or formed through the gate insulating layer GI and the interlayer insulating layer ILD. The second source electrode SE2 may be connected to the source region of the second active pattern ACT2 through a contact hole defined or formed through the gate insulating layer GI and the interlayer insulating layer ILD. The third source electrode SE3 may be connected to the source region of the third active pattern ACT3 through a contact hole defined or formed through the gate insulating layer GI and the interlayer insulating layer ILD.

The first, second, and third drain electrodes DE1, DE2, and DE3 may be disposed on the interlayer insulating layer ILD. The first drain electrode DE1 may be connected to the drain region of the first active pattern ACT1 through a contact hole defined or formed through the gate insulating layer GI and the interlayer insulating layer ILD. The second drain electrode DE2 may be connected to the drain region of the second active pattern ACT2 through a contact hole defined or formed through the gate insulating layer GI and the interlayer insulating layer ILD. The third drain electrode DE3 may be connected to the drain region of the third active pattern ACT3 through a contact hole defined or formed through the gate insulating layer GI and the interlayer insulating layer ILD.

In an embodiment, for example, each of the first, second, and third source electrodes SE1, SE2, and SE3 may include metal, alloy, metal nitride, conductive metal oxide, transparent conductive material, or the like. These can be used alone or in combination with each other. The first, second, and third drain electrodes DE1, DE2, and DE3 may be formed through the same process as the first, second, and third source electrodes SE1, SE2, and SE3, and may include a same material as the first, second, and third source electrodes SE1, SE2, and SE3.

The via insulating layer VIA may be disposed on the interlayer insulating layer ILD. The via insulating layer VIA may sufficiently cover the first, second, and third source electrodes SE1, SE2, and SE3 and the first, second, and third drain electrodes DE1, DE2, and DE3. The via insulating layer VIA may include an organic material. In an embodiment, for example, the via insulating layer VIA may include an organic material such as phenolic resin, polyacrylates resin, polyimides resin, polyamides resin, siloxane resin, epoxy resin, or the like. These can be used alone or in combination with each other.

The first, second, and third pixel electrodes PE1, PE2, and PE3 may be disposed on the via insulating layer VIA. The first pixel electrode PE1 may overlap the first pixel area PX1, the second pixel electrode PE2 may overlap the second pixel area PX2, and the third pixel electrode PE3 may overlap the third pixel area PX3 in the plan view. The first pixel electrode PE1 may be connected to the first drain electrode DE1 (or the first source electrode SE1) through a contact hole defined or formed through the interlayer insulating layer VIA and the second pixel electrode PE2 may be connected to the second drain electrode DE2 (or the second source electrode SE2) through a contact hole defined or formed through the interlayer insulating layer VIA. In addition, the third pixel electrode PE3 may be connected to the third drain electrode DE3 (or third source electrode SE3) through a contact hole defined or formed through the interlayer insulating layer VIA. In an embodiment, for example, the first, second, and third pixel electrodes PE1, PE2, and PE3 may each function as an anode electrode.

In an embodiment, for example, each of the first, second, and third pixel electrodes PE1, PE2, and PE3 may include metal, alloy, metal nitride, conductive metal oxide, transparent conductive material, or the like. These can be used alone or in combination with each other.

The first, second, and third pixel protective layers PL1, PL2, and PL3 may be disposed on the first, second, and third pixel electrodes PE1, PE2, and PE3, respectively. That is, the first pixel protective layer PL1 may be directly disposed on the first pixel electrode PE1, the second pixel protective layer PL2 may be directly disposed on the second pixel electrode PE2, and the third pixel protective layer PL3 may be directly disposed on the third pixel electrode PE3. The first pixel protective layer PL1 may expose at least a portion of the first pixel electrode PE1, the second pixel protective layer PL2 may expose at least a portion of the second pixel electrode PE2, and the third pixel protective layer PL3 may expose at least a portion of the third pixel electrode PE3.

Each of the first, second, and third pixel protective layers PL1, PL2, and PL3 may include a conductive material. In an embodiment, each of the first, second, and third pixel protective layers PL1, PL2, and PL3 may include a conductive metal oxide. In an embodiment, for example, each of the first, second, and third pixel protective layers PL1, PL2, and PL3 may include indium gallium oxide (IGO), indium zinc oxide (IZO), indium tin oxide (ITO), indium zinc tin oxide (IZTO), indium gallium zinc oxide (IGZO), or the like. These can be used alone or in combination with each other. However, embodiments of the disclosure are not necessarily limited thereto.

The pixel defining layer PDL may be disposed on the via insulating layer VIA, the first, second, and third pixel electrodes PE1, PE2, and PE3, and the first, second, and third pixel protective layers PL1, PL2, and PL3. The pixel defining layer PDL may cover the edges of each of the first, second, and third pixel electrodes PE1, PE2, and PE3. In addition, the pixel defining layer PDL may cover the first, second, and third pixel protective layers PL1, PL2, and PL3. A pixel opening exposing at least a portion of an upper surface of each of the first, second, and third pixel electrodes PE1, PE2, and PE3 may be defined in the pixel defining layer PDL. That is, first to third pixel areas PX1, PX2, and PX3 may be defined by the pixel opening of the pixel defining layer PDL.

In an embodiment, the pixel defining layer PDL may include an inorganic material. In an embodiment, for example, the pixel defining layer PDL may include silicon oxide, silicon nitride, silicon oxynitride, magnesium fluoride (MgFₓ), or the like. These can be used alone or in combination with each other. However, embodiments of the disclosure are not necessarily limited thereto, and the pixel defining layer PDL may include an organic material. In addition, the pixel defining layer PDL may have a single-layer structure or a multi-layer structure including a plurality of layers.

In an embodiment, for example, the pixel defining layer PDL may have a tapered shape with a side surface oblique with respect to an upper surface of the substrate SUB or the third direction DR3. In such an embodiment, as shown in FIG. 3, a first angle θ1 between the side surface of the pixel defining layer PDL and a lower surface of the pixel defining layer PDL may have a predetermined value. In an embodiment, the first angle θ1 may be in a range from about 40 degrees to about 90 degrees.

The side wall SW may be disposed on the pixel defining layer PDL. In an embodiment, the side wall SW may be disposed directly on the pixel defining layer PDL. The side wall SW may be disposed between adjacent pixel areas. The side wall SW may have a multi-layer structure including a plurality of layers. In an embodiment, for example, the side wall SW may include a first sub-layer SL1 and a second sub-layer SL2 sequentially disposed on the pixel defining layer PDL.

The first sub-layer SL1 may be directly disposed on the pixel defining layer PDL. The first sub-layer SL1 may include a conductive material. In an embodiment, the first sub-layer SL1 may include aluminum (Al), chromium (Cr), titanium (Ti), gold (Au), indium tin oxide (ITO), or the like. These can be used alone or in combination with each other. In an embodiment, for example, the first sub-layer SL1 may include aluminum (Al).

The second sub-layer SL2 may be directly disposed on the first sub-layer SL1. The second sub-layer SL2 may protect the first sub-layer SL1 from corrosion, oxidation, or the like. The second sub-layer SL2 may include a conductive material. The second sub-layer SL2 may include a conductive material different from that of the first sub-layer SL1. In an embodiment, for example, the first sub-layer SL1 may include aluminum (Al), and the second sub-layer SL2 may include titanium (Ti). However, embodiments of the disclosure are not necessarily limited to this, and the second sub-layer SL2 may include an inorganic material different from the first sub-layer SL1.

In an embodiment, for example, the first sub-layer SL1 may have a tapered shape with a first side surface S1 oblique with respect to the upper surface of the substrate SUB or the third direction DR3. In such an embodiment, a second angle θ2 between the first side surface S1 of the first sub-layer SL1 and a lower surface of the first sub-layer SL1 may have a predetermined value. The second angle θ2 may be different from the first angle θ1. In an embodiment, for example, the second angle θ2 may be greater than the first angle θ1. However, embodiments of the disclosure are not limited thereto. In an embodiment, the second angle θ2 may be in a range from about 70 degrees to about 90 degrees.

In an embodiment, the side wall SW may have an undercut structure UC. In an embodiment, for example, the first sub-layer SL1 and the second sub-layer SL2 may define the undercut structure UC. That is, the second side surface S2 of the second sub-layer SL2 may protrude more toward a center of the pixel opening than the first side surface S1 of the first sub-layer SL1 in the plan view. In other words, a width of the first sub-layer SL1 in the horizontal direction (e.g., the first direction DR1 of FIG. 1) may be smaller than a width of the second sub-layer SL2 in the horizontal direction. Accordingly, the side wall SW including the first sub-layer SL1 and the second sub-layer SL2 may have the undercut structure UC.

A height H of the first sub-layer SL1 may have a predetermined ratio to a length L of a protruding portion of the second sub-layer SL2 in the horizontal direction, that is, a ratio of the height H of the first sub-layer SL1 to the length L of the protruding portion of the second sub-layer SL2 in the horizontal direction may have a predetermined value. In an embodiment, the height H of the first sub-layer SL1 may be in a range from about 1 to about 2 times the length L of the protruding portion of the second sub-layer SL2 in the horizontal direction.

The first light emitting layer EL1 may be disposed on the first pixel electrode PE1 and the side wall SW, the second light emitting layer EL2 may be disposed on the second pixel electrode PE2 and the side wall SW, and the third light emitting layer EL3 may be disposed on the pixel electrode PE3 and the side wall SW. In an embodiment, the first light emitting layer EL1 may be disposed inside the pixel opening defining the first pixel area PX1, the second light emitting layer EL2 may be disposed inside the pixel opening defining the second pixel area PX2, and the third light emitting layer EL3 may be disposed inside the pixel opening defining the third pixel area PX3.

Each of the first, second, and third light emitting layers EL1, EL2, and EL3 may include a light emitting material layer and a functional layer. In an embodiment, for example, the functional layer may include a hole transport layer, a hole injection layer, an electron transport layer, an electron injection layer, or the like, and the light emitting material layer may include an organic light emitting layer. However, embodiments of the disclosure are not necessarily limited thereto.

The light emitting material layer of the first light emitting layer EL1 may include a light emitting material that generates light of the first color, the light emitting material layer of the second light emitting layer EL2 may include a light emitting material that generates light of the second color, and the light emitting material layer of the third light emitting layer EL3 may include a light emitting material that generates light of the third color. In an embodiment, the first color may be red, the second color may be green, and the third color may be blue. In such an embodiment, the first, second, and third light emitting layers EL1, EL2, and EL3 may be spaced apart from each other. That is, the first, second, and third light emitting layers EL1, EL2, and EL3 may be formed through separate processes.

However, embodiments of the disclosure are not necessarily limited thereto. Alternatively, each of the first, second, and third light emitting layers EL1, EL2, and EL3 may include two or more light emitting material layers, and the light emitting material layers may be combined to generate white light. In such an embodiment, the first, second, and third light emitting layers EL1, EL2, and EL3 may be formed integrally without being spaced apart from each other. That is, the first, second, and third light emitting layers EL1, EL2, and EL3 may be formed simultaneously through a same process.

Each of the first, second, and third light emitting layers EL1, EL2, and EL3 may be disconnected by the undercut structure UC of the side wall SW. Accordingly, the first light emitting layer EL1 may be disposed on a first light emitting portion directly contacting the first pixel electrode PE1 and a second light emitting portion disposed on the side wall SW and disconnected from the first light emitting portion in the first pixel area PX1. The second light emitting layer EL2 may be disposed on a third light emitting portion directly contacting the second pixel electrode PE2 and a fourth light emitting portion disposed on the side wall SW and disconnected from the second light emitting portion in the second pixel area PX2. The third light emitting layer EL3 may be disposed on a fifth light emitting portion directly contacting the third pixel electrode PE3 and a sixth light emitting portion disposed on the side wall SW and disconnected from the third light emitting portion in the third pixel area PX3.

In addition, the second light emitting portion of the first light emitting layer EL1 may directly contact the side wall SW, the fourth light emitting portion of the second light emitting layer EL2 may directly contact the side wall SW, and the sixth light emitting portion of the third light emitting layer EL3 may directly contact the side wall SW.

The first common electrode CE1 may be disposed on the first emitting layer EL1, the second common electrode CE2 may be disposed on the second emitting layer EL2, and the third common electrode CE3 may be disposed on the third emitting layer EL3. In an embodiment, the first common electrode CE1 may directly contact an upper surface of the first light emitting layer EL1, the second common electrode CE2 may directly contact an upper surface of the second light emitting layer EL2, and the third common electrode CE3 may directly contact an upper surface of the third light emitting layer EL3.

The first common electrode CE1 may overlap the first pixel area PX1, the second common electrode CE2 may overlap the second pixel area PX2, and the third common electrode CE3 may overlap the third pixel area PX3.

In an embodiment, for example, each of the first, second, and third common electrodes CE1, CE2, and CE3 may include metal, alloy, metal nitride, conductive metal oxide, transparent conductive material, or the like. These can be used alone or in combination with each other. Each of the first, second, and third common electrodes CE1, CE2, and CE3 may function as a cathode electrode.

The first, second, and third common electrodes CE1, CE2, and CE3 may be disconnected by an undercut structure UC on the side wall SW. Accordingly, the first common electrode CE1 may be disposed on a first common portion directly contacting the first light emitting portion of the first light emitting layer EL1 and a second common portion disposed on the side wall SW and disconnected from the first common portion in the first pixel area PX1. The second common electrode CE2 may be disposed on a third common portion directly contacting the third light emitting portion of the second light emitting layer EL2 and a fourth common portion disposed on the side wall SW and disconnected from the third common portion in the second pixel area PX2. The second common electrode CE2 may be disposed on a third common portion directly contacting the third light emitting portion of the second light emitting layer EL2 and a fourth common portion disposed on the side wall SW and disconnected from the third common portion in the second pixel area PX2. The third common electrode CE3 may be disposed on a fifth common portion directly contacting the fifth light emitting portion of the third light emitting layer EL3 and a sixth common portion disposed on the side wall SW and disconnected from the fifth common portion in the third pixel area PX3.

In addition, the second common portion of the first common electrode CE1 may directly contact the second light emitting portion of the first light emitting layer EL1, the fourth common portion of the second common electrode CE2 may directly contact the fourth light emitting portion of the second light emitting layer EL2, and the sixth common portion of the third common electrode CE3 may directly contact the sixth light emitting portion of the third light emitting layer EL3.

In an embodiment, for example, the first, second, and third common electrodes CE1, CE2, and CE3 may be spaced apart from each other. In such an embodiment, the first, second, and third common electrodes CE1, CE2, and CE3 may be formed through separate processes. Alternatively, the first, second, and third common electrodes CE1, CE2, and CE3 may be formed integrally without being spaced apart from each other. In such an embodiment, the first, second, and third common electrodes CE1, CE2, and CE3 may be formed simultaneously through a same process, and the first, second, and third light emitting layers EL1, EL2, and EL3 may be combined to generate white light.

In an embodiment, each of the first, second, and third common electrodes CE1, CE2, and CE3 may directly contact at least a portion of a side surface of the side wall SW. In an embodiment, each of the first, second, and third common electrodes CE1, CE2, and CE3 may directly contact at least a portion of the first side surface S1 of the first sub-layer SL1 of the side wall SW. Accordingly, the first, second, and third common electrodes CE1, CE2, and CE3 may be electrically connected to the side wall SW. In such an embodiment, when a power voltage is applied to the side wall SW, the power voltage may be transmitted to the first, second, and third common electrodes CE1, CE2, and CE3.

The first first inorganic encapsulation layer ENC11 may be disposed on the first common electrode CE1, the second first inorganic encapsulation layer ENC12 may be disposed on the second common electrode CE2, and the third first inorganic encapsulation layer ENC13 may be disposed on the second common electrode CE3. In an embodiment, the first first inorganic encapsulation layer ENC11 may overlap the first pixel area PX1, the second first inorganic encapsulation layer ENC12 may overlap the second pixel area PX2, and the third first inorganic encapsulation layer ENC13 may overlap the third pixel area PX3.

The first first, second first, and third first inorganic encapsulation layers ENC11, ENC12, and ENC13 may directly contact an entire upper surface of the first, second, and third common electrodes CE1, CE2, and CE3, respectively. In addition, in an embodiment, each of the first first, second first, and third first inorganic encapsulation layers ENC11, ENC12, and ENC13 may directly contact the side surface of the side wall SW. In an embodiment, each of the first first, second first, and third first inorganic encapsulation layers ENC11, ENC12, and ENC13 may directly contact the first side surface S1 of the first sub-layer SL1 and the second side surface S2 of the second sub-layer SL2.

That is, each of the first first, second first, and third first inorganic encapsulation layers ENC11, ENC12, and ENC13 may not be disconnected by the undercut structure UC of the side wall SW. In other words, the first first inorganic encapsulation layer ENC11 may continuously extend in the first pixel area PX1, the second first inorganic encapsulation layer ENC12 may continuously extend in the second pixel area PX2, and the third first inorganic encapsulation layer ENC13 may continuously extend in the third pixel area PX3.

In an embodiment, for example, each of the first first, second first, and third first inorganic encapsulation layers ENC11, ENC12, and ENC13 may include an inorganic material such as silicon oxide, silicon nitride, silicon oxynitride, or the like. These can be used alone or in combination with each other.

In an embodiment, for example, the first first, second first, and third first inorganic encapsulation layers ENC11, ENC12, and ENC13 may be spaced apart from each other. In such an embodiment, the first first, second first, and third first inorganic encapsulation layers ENC11, ENC12, and ENC13 may be formed through separate processes. Alternatively, the first first, second first, and third first inorganic encapsulation layers ENC11, ENC12, and ENC13 may be formed integrally without being spaced apart from each other. In such an embodiment, the first first, second first, and third first inorganic encapsulation layers ENC11, ENC12, and ENC13 may be formed simultaneously through a same process, and the first, second, and third light emitting layers EL1, EL2, and EL3 may be combined to generate white light.

A portion of the first first inorganic encapsulation layer ENC11 contacting the lower surface of the protruding portion of the second sub-layer SL2 may have a first thickness TH11. In an embodiment, the first thickness TH11 may range from less than about 0.3 micrometer (μm).

in an embodiment, a portion of the second first inorganic encapsulation layer ENC12 contacting the lower surface of the protruding portion of the second sub-layer SL2 may also have the first thickness TH11 and a portion of the third first inorganic encapsulation layer ENC13 contacting the lower surface of the protruding portion of the second sub-layer SL2 may also have the first thickness TH11.

A portion of the first first inorganic encapsulation layer ENC11 contacting the second common portion of the first common electrode CE1 may have a second thickness TH12. In an embodiment, for example, the second thickness TH12 may be in a range from about 0.7 μm or about 1.6 μm. However, embodiments of the disclosure are not limited thereto.

Likewise, a portion of the second first inorganic encapsulation layer ENC12 contacting the fourth common portion of the second common electrode CE2 may also have the second thickness TH12 and a portion of the third first inorganic encapsulation layer ENC13 contacting the fourth common portion of the second common electrode CE2 may also have the second thickness TH12.

The inorganic insulating layer IOL may be disposed on the first first, second first, and third first inorganic encapsulation layers ENC11, ENC12, and ENC13. The inorganic insulating layer IOL may continuously extend across the first pixel area PX1, the second pixel area PX2, and the third pixel area PX3. In an embodiment, for example, the inorganic insulating layer IOL may include an inorganic material such as silicon oxide, silicon nitride, silicon oxynitride, or the like. These can be used alone or in combination with each other.

In an embodiment, for example, the inorganic insulating layer IOL may include an inorganic material different from the first first, second first, and third first inorganic encapsulation layers ENC11, ENC12, and ENC13. Alternatively, the inorganic insulating layer IOL may include the same inorganic material as the first first, second first, and third first inorganic encapsulation layers ENC11, ENC12, and ENC13.

Alternatively, the inorganic insulating layer IOL may be omitted.

The organic encapsulation layer ENC2 may be disposed on the inorganic insulating layer IOL. The organic encapsulation layer ENC2 may continuously extend across the first pixel area PX1, the second pixel area PX2, and the third pixel area PX3. The organic encapsulation layer ENC2 may have a substantially flat upper surface. In an embodiment, for example, the organic encapsulation layer ENC2 may include a cured polymer such as polyacrylate or the like. However, embodiments of the disclosure are not limited thereto.

The second inorganic encapsulation layer ENC3 may be disposed on the organic encapsulation layer ENC2. The second inorganic encapsulation layer ENC3 may continuously extend across the first pixel area PX1, the second pixel area PX2, and the third pixel area PX3. In an embodiment, for example, the second inorganic encapsulation layer ENC3 may include an inorganic material such as silicon oxide, silicon nitride, silicon oxynitride, or the like. These can be used alone or in combination with each other.

A surface area of the first first inorganic encapsulation layer ENC11 may be different from a surface area of the second inorganic encapsulation layer ENC3 in the first pixel area PX1, a surface area of second first inorganic encapsulation layer ENC12 may be different from a surface area of the second inorganic encapsulation layer ENC3 in the second pixel area PX2, and a surface area of third first inorganic encapsulation layer ENC13 may be different from a surface area of the second inorganic encapsulation layer ENC3 in the third pixel area PX3. In an embodiment, the surface area of the first first inorganic encapsulation layer ENC11 may be greater than the surface area of the second inorganic encapsulation layer ENC3 in the first pixel area PX1, the surface area of second first inorganic encapsulation layer ENC12 may be greater than the surface area of the second inorganic encapsulation layer ENC3 in the second pixel area PX2, and the surface area of third first inorganic encapsulation layer ENC13 may be greater than the surface area of the second inorganic encapsulation layer ENC3 in the third pixel area PX3. Accordingly, each of the first first, second first, and third first inorganic encapsulation layers ENC11, ENC12, and ENC13 may have improved step coverage compared to the second inorganic encapsulation layer ENC3.

In an embodiment, as described above, the first angle θ1 may be in a range from about 40 degrees to 90 degrees, and the second angle θ2 may be in a range from about 70 degrees to about 90 degrees. In such an embodiment, an opening ratio of each of the first, second, and third pixel areas PX1, PX2, and PX3 may be about 60%. Accordingly, the surface area of the first first inorganic encapsulation layer ENC11 may be about 30% or more greater than the surface area of the second inorganic encapsulation layer ENC3 in the first pixel area PX1. In such an embodiment, the surface area of the second first inorganic encapsulation layer ENC12 may be about 30% or more greater than the surface area of the second inorganic encapsulation layer ENC3 in the second pixel area PX2 and the surface area of the third first inorganic encapsulation layer ENC13 may be about 30% or more greater than the surface area of the second inorganic encapsulation layer ENC3 in the third pixel area PX3.

An average thickness of each of the first first, second first, and third first inorganic encapsulation layers ENC11, ENC12, and ENC13 may be different from the thickness TH2 of the second inorganic encapsulation layer ENC3. In an embodiment, the average thickness of each of the first first, second first, and third first inorganic encapsulation layers ENC11, ENC12, and ENC13 may be thicker than the thickness TH2 of the second inorganic encapsulation layer ENC3. Accordingly, each of the first first, second first, and third first inorganic encapsulation layers ENC11, ENC12, and ENC13 may have improved step coverage compared to the second inorganic encapsulation layer ENC3.

In such embodiment, as the step coverage of each of the first first, second first, and third first inorganic encapsulation layers ENC11, ENC12, and ENC13 is improved, the portion of the first first inorganic encapsulation layer ENC11 contacting the lower surface of the protruding portion of the second sub-layer SL2 may be allowed to have the first thickness TH11 less than about 0.3 μm. In such an embodiment, as described above, the height H of the first sub-layer SL1 may be in a range from about 1 to about 2 times the length L of the protruding portion of the second sub-layer SL2 in the horizontal direction to allow the portion of the first first inorganic encapsulation layer ENC11 contacting the lower surface of the protruding portion of the second sub-layer SL2 to have the first thickness TH11 less than about 0.3 μm.

In an embodiment, for example, a thickness uniformity of each of the first first, second first, and third first inorganic encapsulation layers ENC11, ENC12, and ENC13 may be about 10% or more.

The display device DD according to embodiments of the disclosure may include a pixel electrode (e.g., the first pixel electrode PE1, the second pixel electrode PE2, or the third pixel electrode PE3) disposed on the substrate SUB, the pixel defining layer PDL defining the pixel opening exposing a least a portion of an upper surface of the pixel electrode, the side wall SW disposed directly on the pixel defining layer PDL and having the undercut structure UC, a light emitting layer (e.g., the first light emitting layer EL1, the second light emitting layer EL2, or the third light emitting layer EL3) disconnected by the undercut structure UC on the side wall SW, a common electrode (e.g., the first common electrode CE1, the second common electrode CE2, or the third common electrode CE3) disconnected by the undercut structure UC on the light emitting layer, and a first inorganic encapsulation layer (e.g., the first first inorganic encapsulation layer ENC11, the second first inorganic encapsulation layer ENC12, or the third first inorganic encapsulation layer ENC13) disposed on the common electrode and directly contact the side surface of the side wall SW. In such embodiments, the surface area of the first inorganic encapsulation layer may greater than the surface area of a second inorganic encapsulation layer ENC3 disposed on the organic encapsulation layer ENC2.

In such embodiments, each of the first angle θ1 between the side surface of the pixel defining layer PDL and the lower surface of the pixel defining layer PDL, the second angle θ2 between the first side surface S1 of a first sub-layer SL1 of the side wall SW and a lower surface of the first sub-layer SL1, the thickness of the portion of the first inorganic encapsulation layer contacting the lower surface of the protruding portion of the second sub-layer SL2 of the side wall SW, and a ratio of the height H of the first sub-layer SL1 to the length L of the protruding portion of a second sub-layer SL2 in the horizontal direction may have a predetermined value. Accordingly, the flexibility of the display device DD may be improved.

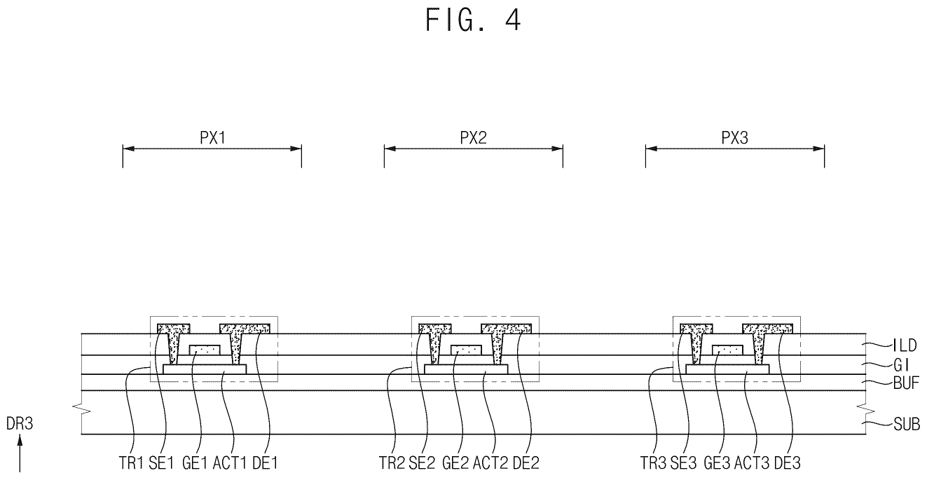

FIGS. 4 to 25 are cross-sectional views showing processes of an embodiment of a method of manufacturing the display device of FIG. 2.

Referring to FIG. 4, in an embodiment of a method of manufacturing the display device, the buffer layer BUF, the first, second, and third active patterns ACT1, ACT2, and ACT3, the gate insulating layer GI, the first, second, and third gate electrodes GE1, GE2, and GE3, the interlayer insulating layer ILD, the first, second, and third source electrodes SE1, SE2, and SE3, and the first, second, and third drain electrodes DE1, DE2, and DE3 may be formed sequentially on the substrate SUB. Accordingly, the first, second, and third transistors TR1, TR2, and TR3 may be formed on the substrate SUB.

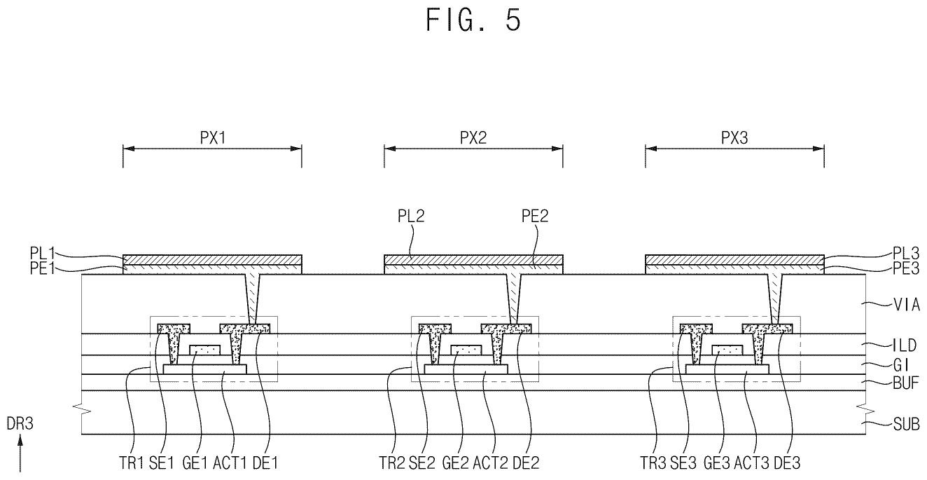

Referring further to FIG. 5, the insulating layer VIA may be formed on the interlayer insulating layer ILD to cover the first, second, and third source electrodes SE1, SE2, and SE3 and the first, second, and third drain electrodes DE1, DE2, and DE3. In an embodiment, for example, the via insulating layer VIA may include or be formed of an organic material.

The first, second, and third pixel electrodes PE1, PE2, and PE3 may be formed on the via insulating layer VIA. The first pixel electrode PE1 may be formed in the first pixel area PX1, the second pixel electrode PE2 may be formed in the second pixel area PX2, and the third pixel electrode PE3 may be formed in the third pixel area PX3.

The first pixel protective layer PL1 may be formed on the first pixel electrode PE1, the second pixel protective layer PL2 may be formed on the second pixel electrode PE2, and the third pixel electrode PE3 may be formed on the third pixel electrode PE3.

The first pixel protective layer PL1 may be formed to cover the entire upper surface of the first pixel electrode PE1, the second pixel protective layer PL2 may be formed to cover the entire upper surface of the second pixel electrode PE2, and the third pixel protective layer PL3 may be formed to cover the entire upper surface of the third pixel electrode PE3. In an embodiment, for example, the first, second, and third pixel protective layers PL1, PL2, and PL3 may be formed using a conductive metal oxide.

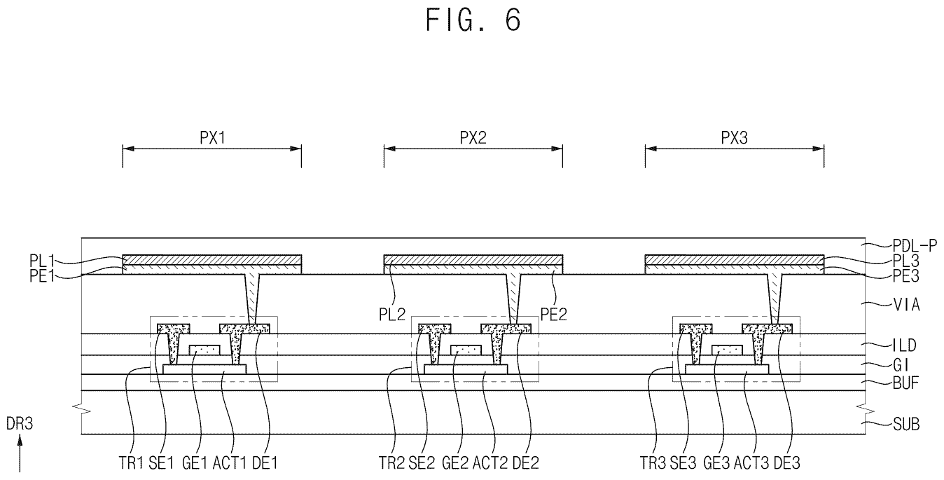

Referring further to FIG. 6, a preliminary pixel defining layer PDL-P may be entirely formed on the via insulating layer VIA. The preliminary pixel defining layer PDL-P may be formed to cover the first, second, and third pixel electrodes PE1, PE2, and PE3 and the first, second, and third pixel protective layers PL1, PL2, and PL3. In an embodiment, for example, the preliminary pixel defining layer PDL-P may be formed using an inorganic material.

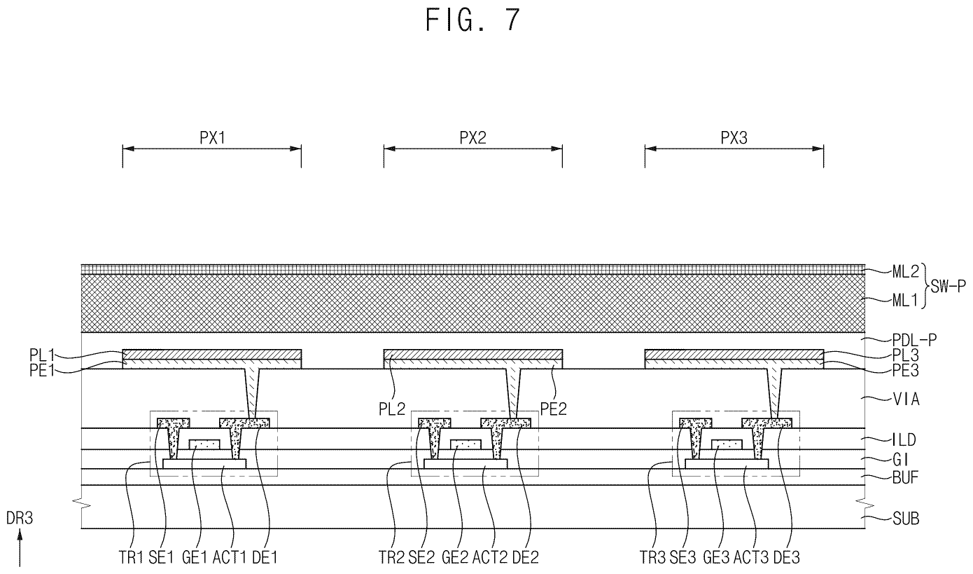

Referring further to FIG. 7, a preliminary side wall SW-P may be entirely formed on the preliminary pixel defining layer PDL-P. The preliminary side wall SW-P may include a first metal layer ML1 formed on the preliminary pixel defining layer PDL-P and a second metal layer ML2 formed on the first metal layer ML1. In an embodiment, for example, the first metal layer ML1 may be formed using aluminum (Al), and the second metal layer ML2 may be formed using titanium (Ti).

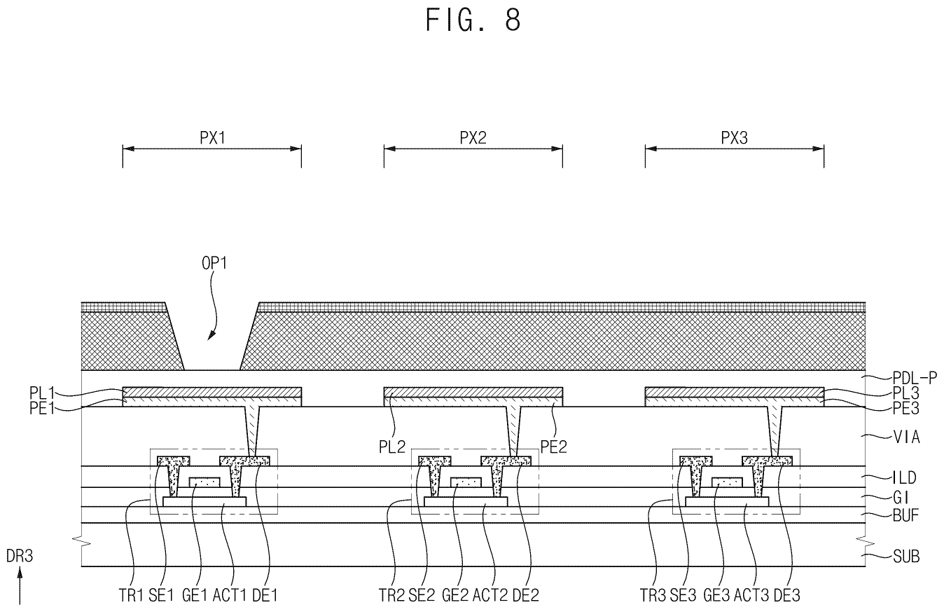

Referring further to FIG. 8, a portion of the preliminary side wall SW-P overlapping the first pixel area PX1 may be removed through a first etching process. Accordingly, in the first pixel area PX1, a first opening OP1 exposing at least a portion of the preliminary pixel defining layer PDL-P may be formed in the preliminary side wall SW-P. In an embodiment, for example, the first etching process may be a dry etching process.

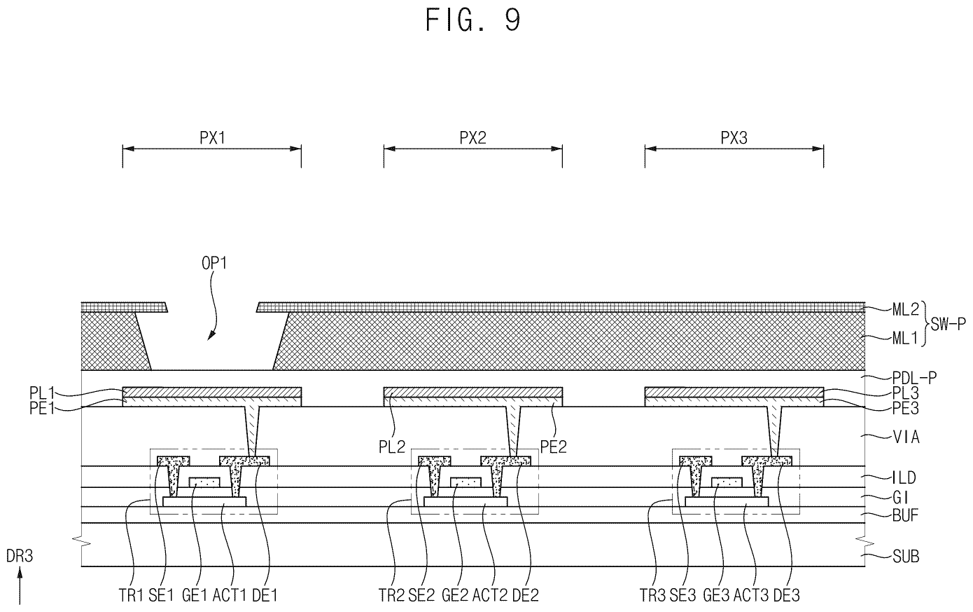

Referring further to FIG. 9, a portion of the first metal layer ML1 exposed by the first opening OP1 may be removed through a second etching process. Accordingly, a width of the first opening OP1 may be expanded. In the second etching process, an etch rate of the second metal layer ML2 may be less than an etch rate of the first metal layer MHL1. That is, the second metal layer ML2 may not be etched by the second etching process. In an embodiment, for example, the second etching process may be a wet etching process.

After performing the second etching process, a side surface of the second metal layer ML2 may protrude further toward a center of first opening OP1 than a side surface of the first metal layer ML1 in the first pixel area PX1. Accordingly, in the first pixel area PX1, the preliminary side wall SW-P may have an undercut structure (see FIG. 3).

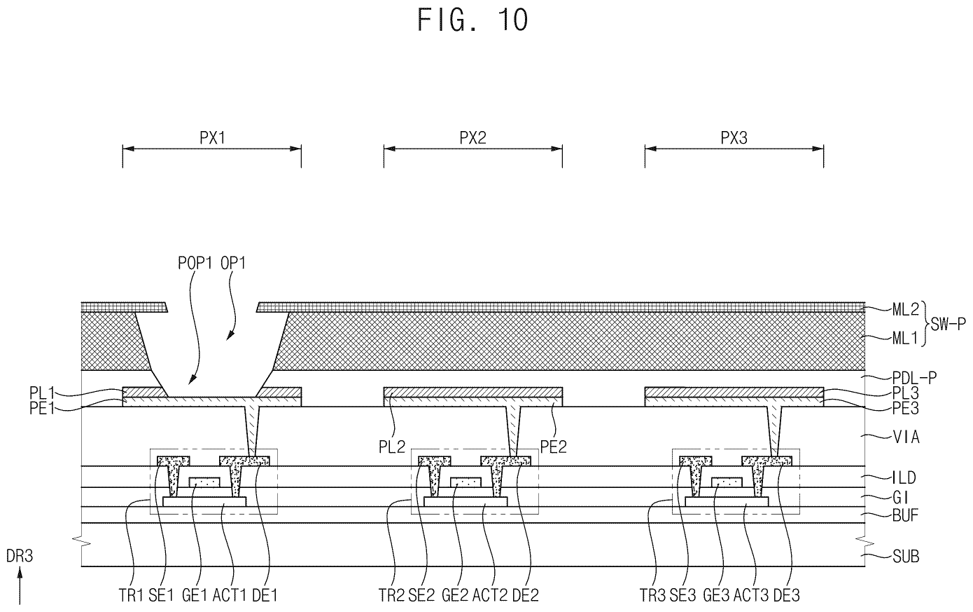

Referring further to FIG. 10, a portion of the preliminary pixel defining layer PDP-P exposed by the first opening OP1 may be removed through a third etching process. Accordingly, a first pixel opening POP1 exposing at least a portion of the first pixel protective layer PL1 may be formed in the preliminary pixel defining layer PDP-P in the first pixel area PX1. In such an embodiment, due to the first pixel protective layer PL1, the first pixel electrode PE1 may not be removed by the third etching process. That is, the first pixel protective layer PL1 may protect the first pixel electrode PE1 from being etched by the third etching process. In an embodiment, for example, the third etching process may be a dry etching process.

Through a fourth etching process, a portion of the first pixel protective layer PL1 exposed by the first pixel opening POP1 may be removed. Accordingly, the first pixel protective layer PL1 may expose at least a portion of the first pixel electrode PE1. In an embodiment, for example, the fourth etching process may be a dry etching process or a wet etching process.

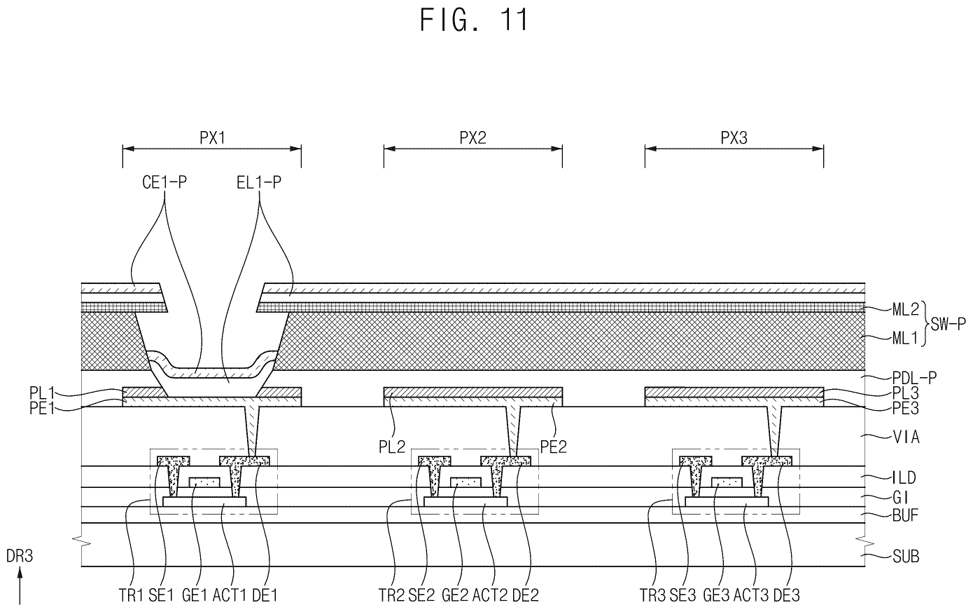

Referring further to FIG. 11, a preliminary first light emitting layer EL1-P may be entirely formed on the preliminary side wall SW-P and the first pixel electrode PE1. In addition, the preliminary first light emitting layer EL1-P may also be formed inside the first pixel opening POP1. The preliminary first light emitting layer EL1-P may be disconnected in the first pixel area PX1 by the undercut structure of the preliminary side wall SW-P. In an embodiment, for example, the preliminary first light emitting layer EL1-P may include a light emitting material layer including or formed of a light emitting material that generates light of the first color and a functional layer.

A preliminary first common electrode CE1-P may be entirely formed on the preliminary first light emitting layer EL1-P. In addition, the preliminary first common electrode CE1-P may be formed to contact the entire upper surface of the preliminary first light emitting layer EL1-P. The preliminary first common electrode CE1-P may be disconnected in the first pixel area PX1 by the undercut structure of the preliminary side wall SW-P.

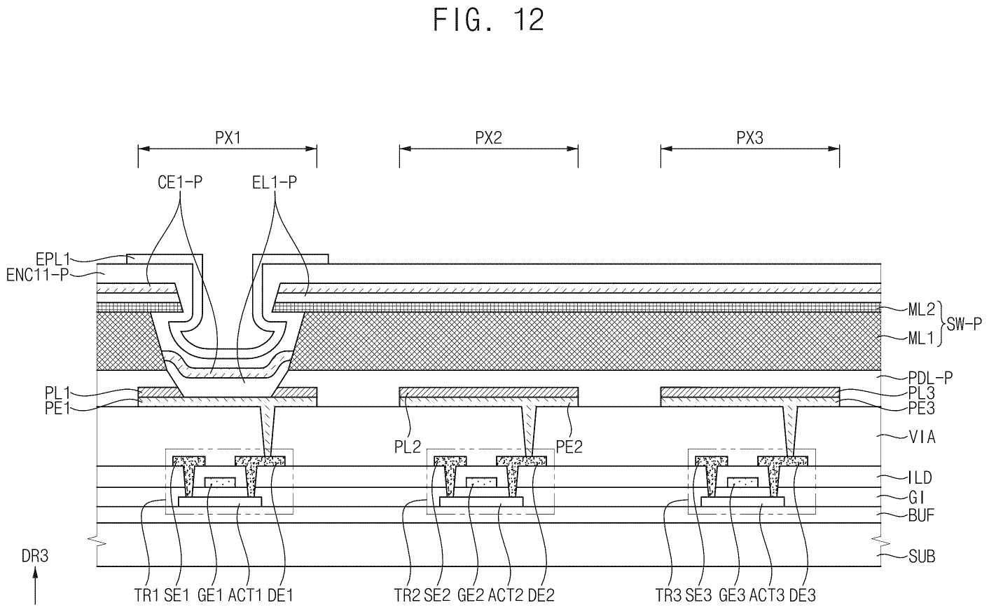

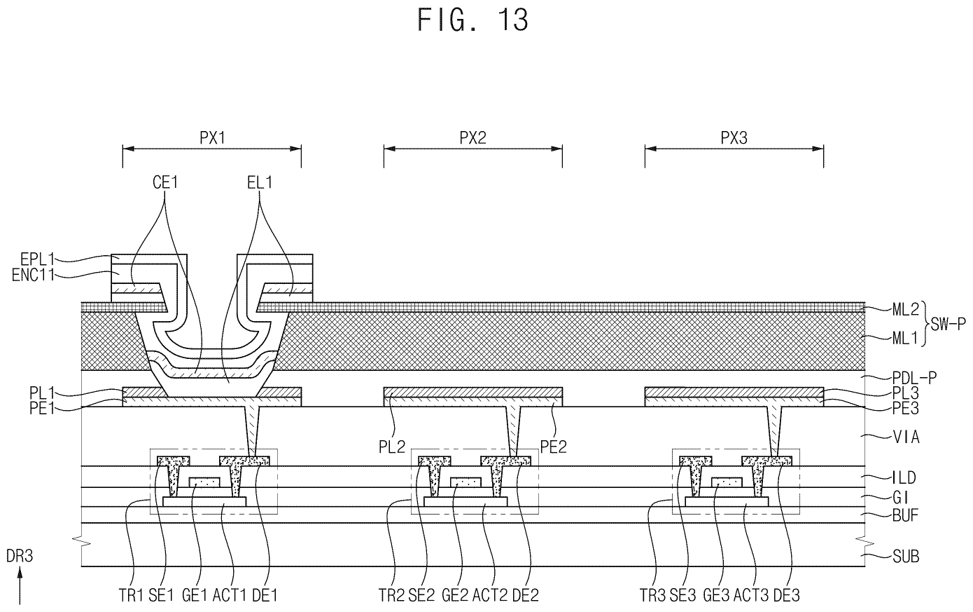

Referring further to FIGS. 12 and 13, a preliminary first first inorganic encapsulation layer ENC11-P may be entirely formed on the preliminary first common electrode CE1-P. The preliminary first first inorganic encapsulation layer ENC11-P may be continuously extended into the first opening OP1 without being disconnected by the undercut structure of the preliminary side wall SW-P.

In an embodiment, for example, the preliminary first first inorganic encapsulation layer ENC11-P may be formed using an inorganic material such as silicon oxide, silicon nitride, silicon oxynitride, or the like.

A first sacrificial protective layer EPL1 may be formed in the first pixel area PX1 on the preliminary first first inorganic encapsulation layer ENC11-P. In an embodiment, for example, the first sacrificial protective layer EPL1 may be formed using a conductive metal oxide.

Through a fifth etching process, a portion of the preliminary first light emitting layer EL1-P, a portion of the preliminary first common electrode CE1-P, and a portion of the preliminary first first inorganic encapsulation layer ENC11-P that does not overlap the first sacrificial protective layer EPL1 may be removed. Accordingly, the first light emitting layer EL1, the first common electrode CE1 on the first light emitting layer EL1, and the first first inorganic encapsulation layer ENC11 on the first common electrode CE1 may be formed in the first pixel area PX1. In an embodiment, for example, the fifth etching process may be a dry etching process or a wet etching process.

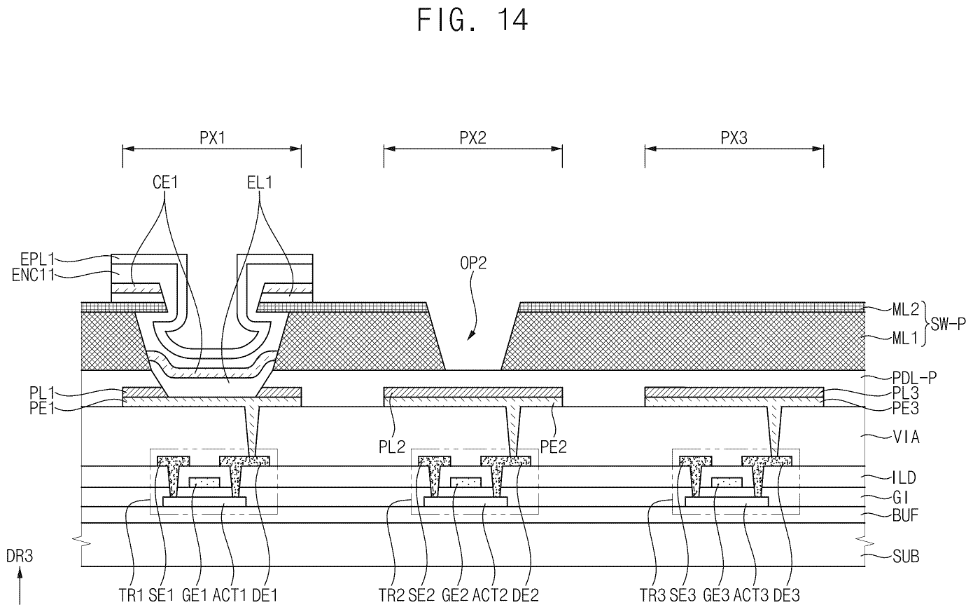

Referring further to FIG. 14, a portion of the preliminary side wall SW-P overlapping the second pixel area PX2 may be removed through a sixth etching process. Accordingly, in the second pixel area PX2, a second opening OP2 exposing at least a portion of the preliminary pixel defining layer PDL-P may be formed in the preliminary side wall SW-P. In an embodiment, for example, the sixth etching process may be a dry etching process.

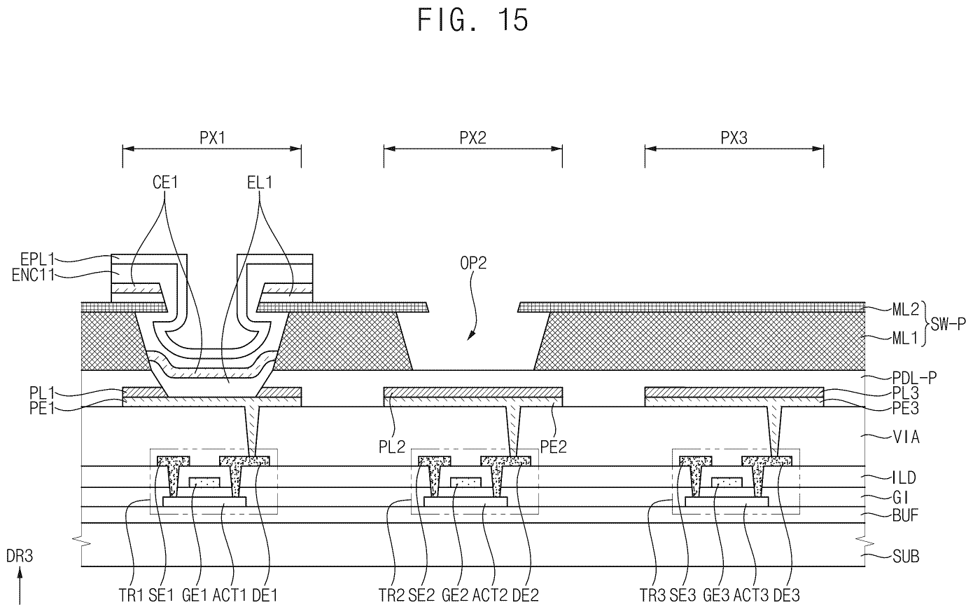

Referring further to FIG. 15, a portion of the first metal layer ML1 exposed by the second opening OP2 may be removed through a seventh etching process. Accordingly, a width of the second opening OP2 may be expanded. In the seventh etching process, an etch rate of the second metal layer ML2 may be less than an etch rate of the first metal layer ML1. That is, the second metal layer ML2 may not be etched by the seventh etching process. In an embodiment, for example, the seventh etching process may be a wet etching process.

After performing the seventh etching process, a side surface of the second metal layer ML2 may protrude further to a center of the second opening OP2 than a side surface of the first metal layer ML1 in the second pixel area PX2. Accordingly, in the second pixel area PX2, the preliminary side wall SW-P may have the undercut structure (see FIG. 3).

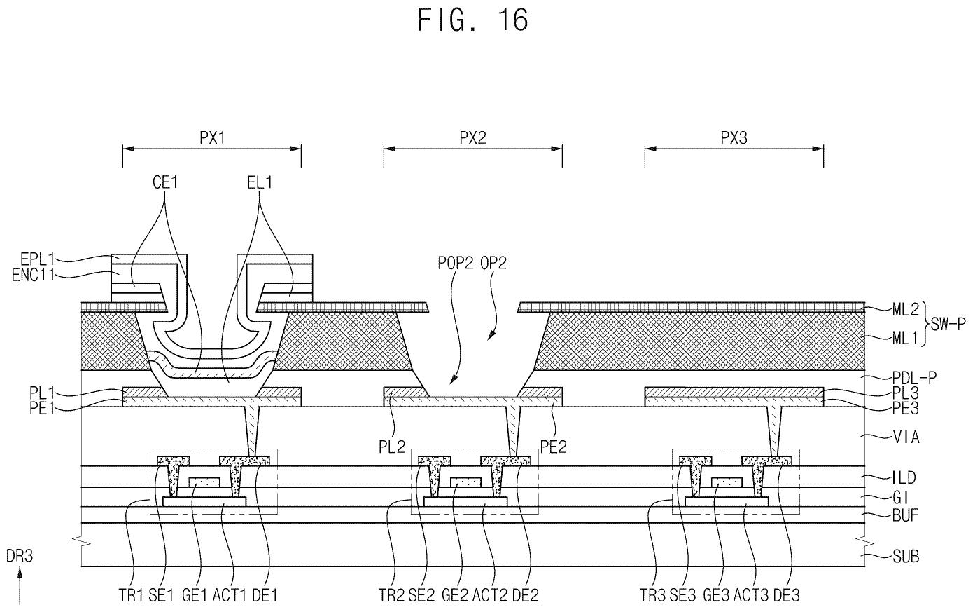

Referring further to FIG. 16, a portion of the preliminary pixel defining layer PDP-P exposed by the second opening OP2 may be removed through an eighth etching process. Accordingly, a second pixel opening POP2 exposing at least a portion of the first pixel protective layer PL1 may be formed in the preliminary pixel defining layer PDP-P in the second pixel area PX2. In such an embodiment, due to the second pixel protective layer PL2, the second pixel electrode PE2 may not be removed by the eighth etching process. That is, the second pixel protective layer PL2 may protect the second pixel electrode PE2 from being etched by the eighth etching process. In an embodiment, for example, the eighth etching process may be a dry etching process.

Through a ninth etching process, a portion of the second pixel protective layer PL2 exposed by the second pixel opening POP2 may be removed. Accordingly, the second pixel protective layer PL2 may expose at least a portion of the second pixel electrode PE2. In an embodiment, for example, the ninth etching process may be a dry etching process or a wet etching process.

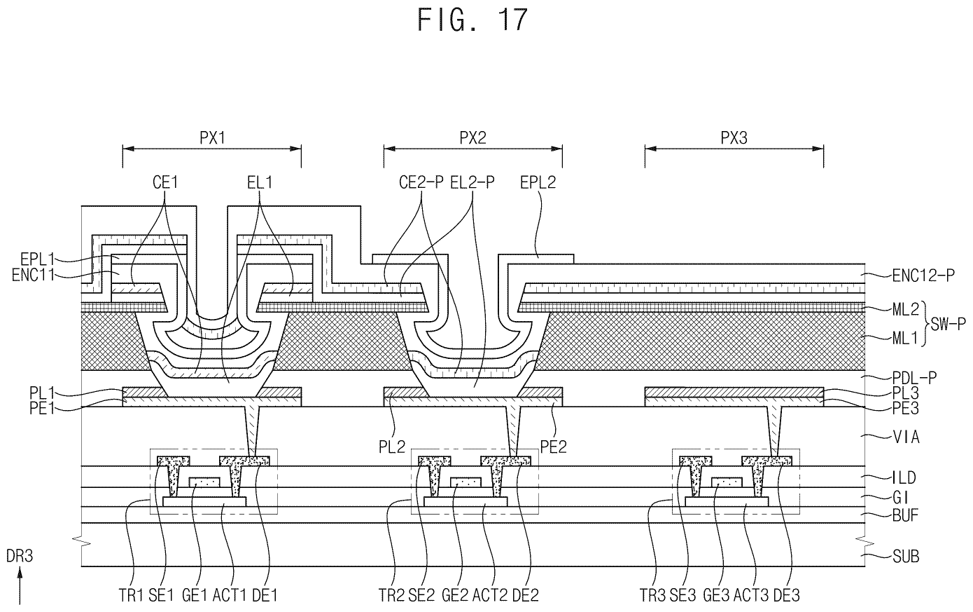

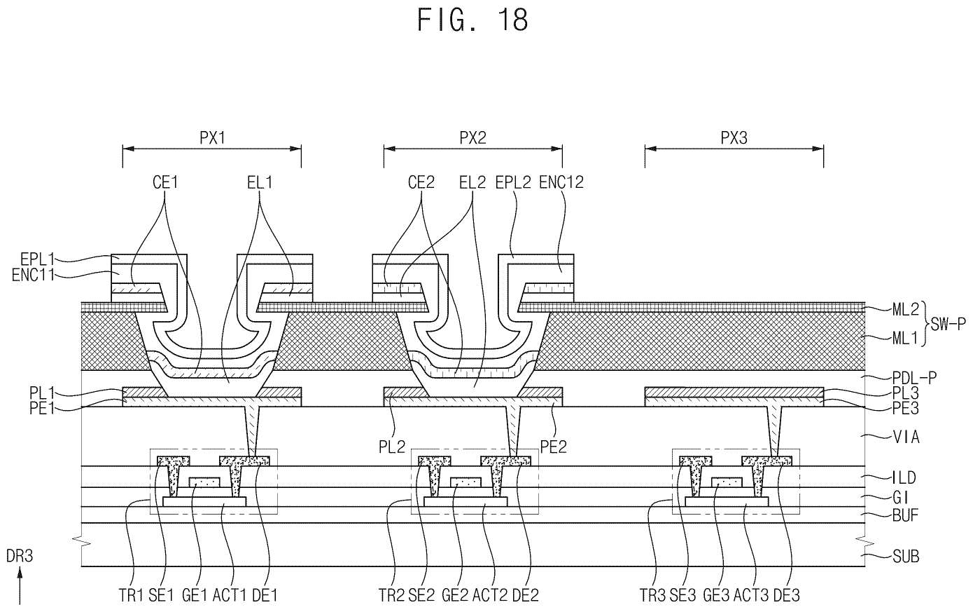

Referring further to FIGS. 17 and 18, a preliminary second light emitting layer EL2-P may be entirely formed on the first sacrificial protective layer EPL1, the preliminary side wall SW-P, and the second pixel electrode PE2. In addition, the preliminary second light emitting layer EL2-P may also be formed inside the second pixel opening POP2. The preliminary second light emitting layer EL2-P may be disconnected from the first pixel area PX1 and the second pixel area PX2 by the undercut structure of the preliminary side wall SW-P. In an embodiment, for example, the preliminary second light emitting layer EL2-P may include a light emitting material layer including or formed of a light emitting material that generates light of the second color and a functional layer.

The preliminary second common electrode CE2-P may be entirely formed on the preliminary second light emitting layer EL2-P. In addition, the preliminary second common electrode CE2-P may be formed to contact the entire upper surface of the preliminary second light emitting layer EL2-P. The preliminary second common electrode CE2-P may be disconnected from the first pixel area PX1 and the second pixel area PX2 by the undercut structure of the preliminary side wall SW-P.

The preliminary second first inorganic encapsulation layer ENC12-P may be entirely formed on the preliminary second common electrode CE2-P. The preliminary second first inorganic encapsulation layer ENC12-P is not disconnected by the undercut structure of the preliminary side wall SW-P, but may continuously extend into the first opening OP1 and the second opening OP2.

In an embodiment, for example, the preliminary second first inorganic encapsulation layer ENC12-P may be formed using an inorganic material such as silicon oxide, silicon nitride, silicon oxynitride, or the like.

A second sacrificial protective layer EPL2 may be formed in the second pixel area PX2 on the preliminary second first inorganic encapsulation layer ENC12-P. In an embodiment, for example, the second sacrificial protective layer EPL2 may be formed using a conductive metal oxide.

Through a tenth etching process, a portion of the preliminary second light emitting layer EL2-P, a portion of the preliminary second common electrode CE2-P, and a portion of the preliminary second first inorganic encapsulation layer ENC12-P that does not overlap the second sacrificial protective layer EPL2 may be removed. Accordingly, the second light emitting layer EL2, the second common electrode CE2 on the second light emitting layer EL2, and the second first inorganic encapsulation layer ENC12 on the second common electrode CE2 may be formed in the second pixel area PX2. In an embodiment, for example, the tenth etching process may be a dry etching process or a wet etching process.

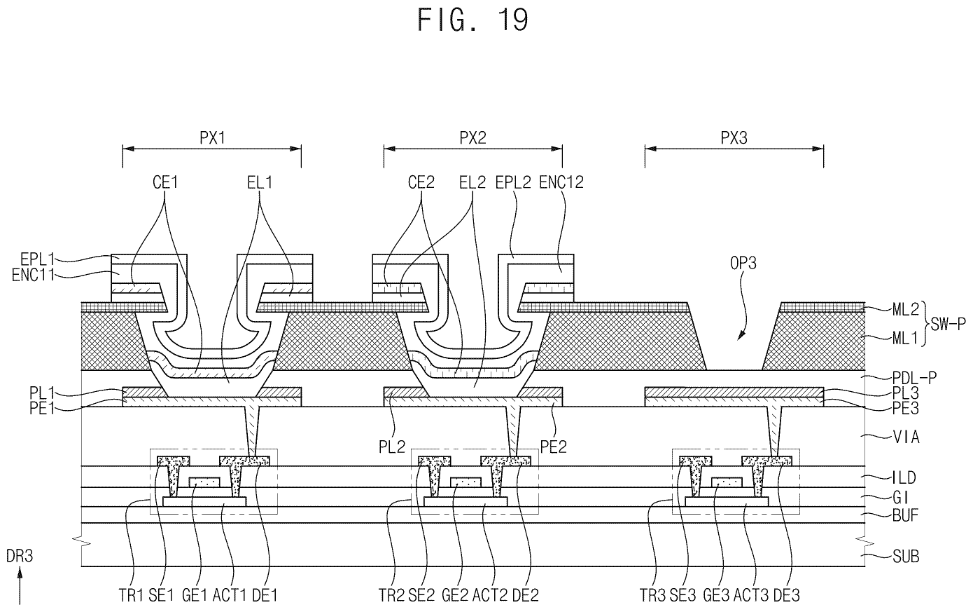

Referring further to FIG. 19, a portion of the preliminary side wall SW-P overlapping the third pixel area PX3 may be removed through an eleventh etching process. Accordingly, in the third pixel area PX3, a third opening OP3 exposing at least a portion of the preliminary pixel defining layer PDL-P may be formed in the preliminary side wall SW-P. In an embodiment, for example, the eleventh etching process may be a dry etching process.

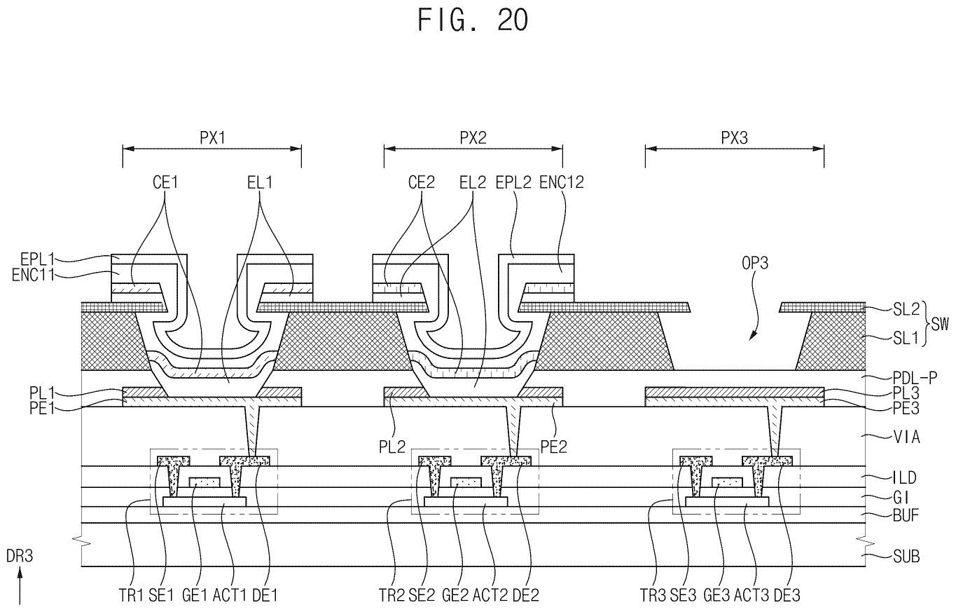

Referring further to FIG. 20, a portion of the first metal layer ML1 exposed by the third opening OP3 may be removed through a twelfth etching process. Accordingly, a width of the third opening OP3 may be expanded. As the third opening OP3 is expanded, the side wall SW including the first sub-layer SL1 and the second sub-layer SL2 on the first sub-layer SL1 may be formed. That is, after performing the twelfth etching process, the side wall SW may have the undercut structure in the third pixel area PX3 (see FIG. 3). The side wall SW may have the undercut structure in each of the first, second, and third pixel areas PX1, PX2, and PX3.

In the twelfth etching process, an etch rate of the second metal layer ML2 may be less than an etch rate of the first metal layer ML1. That is, the second metal layer ML2 may not be etched by the twelfth etching process. In an embodiment, for example, the twelfth etching process may be a wet etching process.

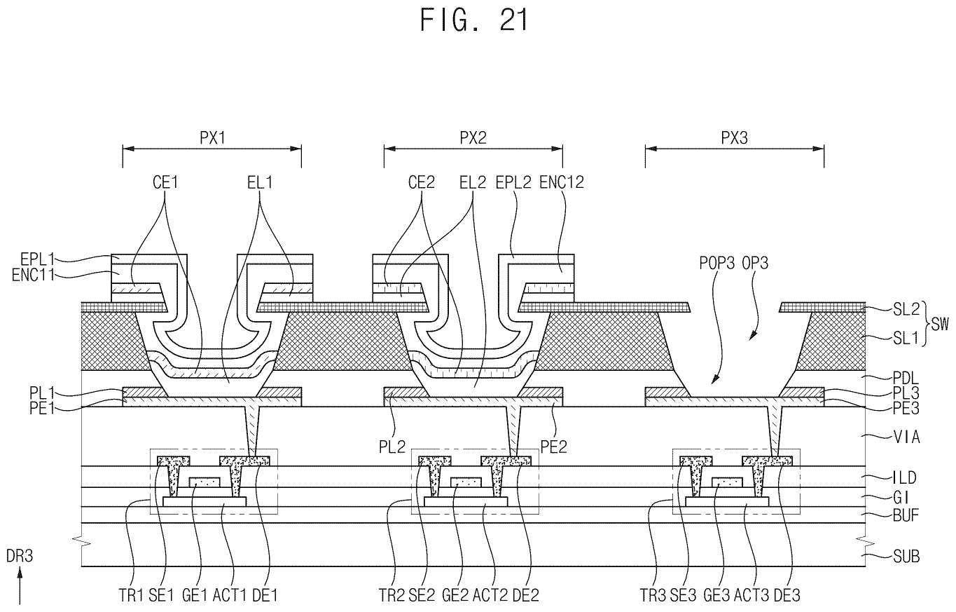

Referring further to FIG. 21, a portion of the preliminary pixel defining layer PDP-P exposed by the third opening OP3 may be removed through a thirteenth etching process. Accordingly, a third pixel opening POP3 exposing at least a portion of the third pixel protective layer PL3 may be formed in the third pixel area PX3. That is, after performing the thirteenth etching process, the pixel defining layer PDL in which the first, second, and third pixel openings POP1, POP2, and POP3 are defined may be formed.

In such an embodiment, due to the third pixel protective layer PL3, the third pixel electrode PE3 may not be removed by the thirteenth etching process. That is, the third pixel protective layer PL3 may protect the third pixel electrode PE3 from being etched by the thirteenth etching process. In an embodiment, for example, the thirteenth etching process may be a dry etching process.

Through a fourteenth etching process, a portion of the third pixel protective layer PL3 exposed by the third pixel opening POP3 may be removed. Accordingly, the third pixel protective layer PL3 may expose at least a portion of the third pixel electrode PE3. In an embodiment, for example, the fourteenth etching process may be a dry etching process or a wet etching process.

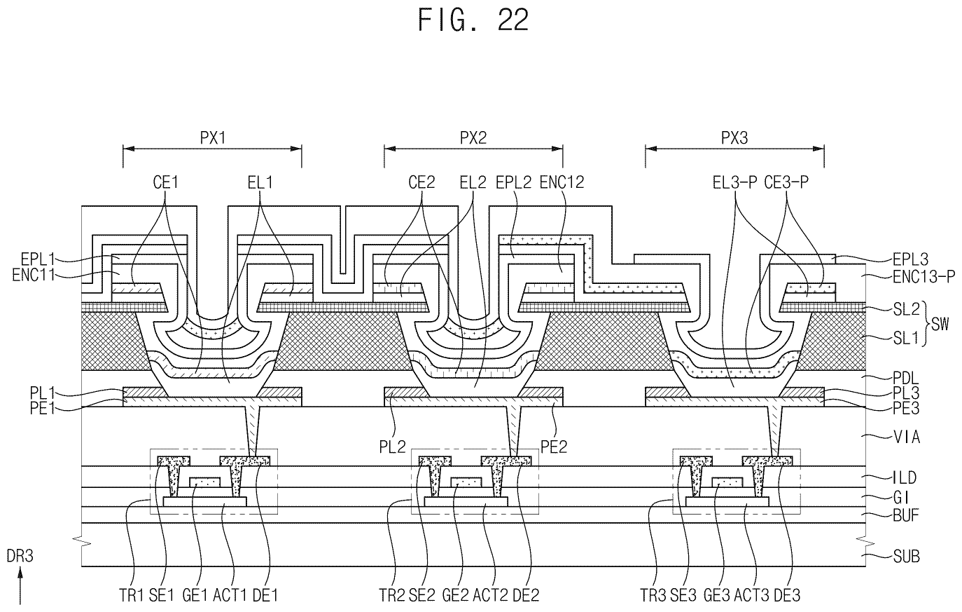

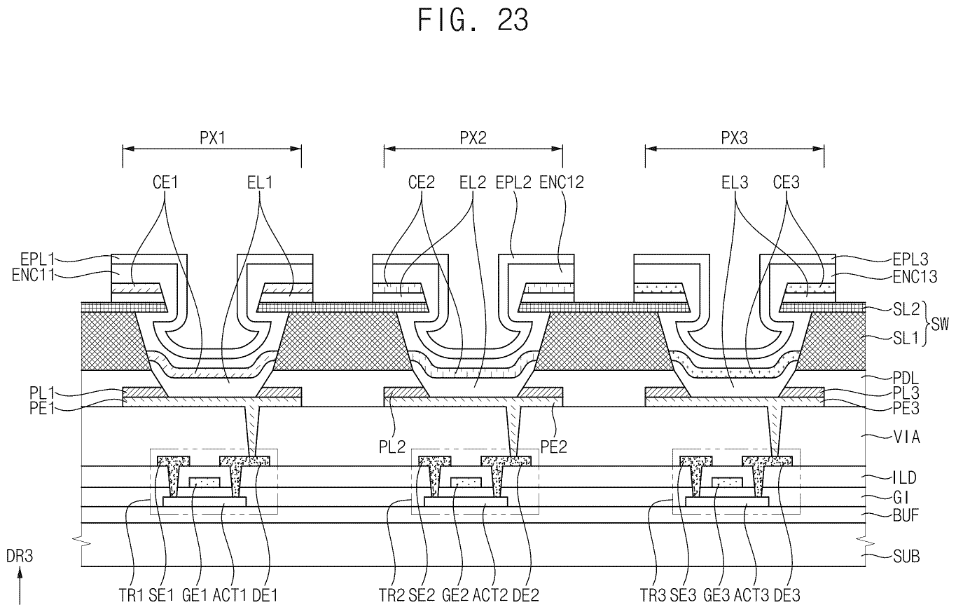

Referring further to FIGS. 22 and 23, a preliminary third light emitting layer EL3-P may be entirely formed on the first sacrificial protective layer EPL1, the second sacrificial protective layer EPL2, the side wall SW, and the third pixel electrode PE3. In addition, the preliminary third light emitting layer EL3-P may also be formed inside the third pixel opening POP3. The preliminary third light emitting layer EL3-P may be disconnected in the first, second, and third pixel areas PX1, PX2, and PX3 by the undercut structure of the side wall SW. In an embodiment, for example, the preliminary third light emitting layer EL3-P may include a light emitting material layer including or formed of a light emitting material that generates light of the third color and a functional layer.

A preliminary third common electrode CE3-P may be entirely formed on the preliminary third light emitting layer EL3-P. In addition, the preliminary third common electrode CE3-P may be formed to contact the entire upper surface of the preliminary third light emitting layer EL3-P. The preliminary third common electrode CE3-P may be disconnected from the first, second, and third pixel areas PX1, PX2, and PX3 by the undercut structure of the side wall SW.

A preliminary third first inorganic encapsulation layer ENC13-P may be entirely formed on the preliminary third common electrode CE3-P. The preliminary third first inorganic encapsulation layer ENC13-P may be continuously extended into the first, second, and third openings OP1, OP2, and OP3 without being disconnected by the undercut structure of the side wall SW.

In an embodiment, for example, the preliminary third first inorganic encapsulation layer ENC13-P may be formed using an inorganic material such as silicon oxide, silicon nitride, silicon oxynitride, or the like.

A third sacrificial protective layer EPL3 may be formed in the third pixel area PX3 on the preliminary third first inorganic encapsulation layer ENC13-P. In an embodiment, for example, the third sacrificial protective layer EPL3 may be formed using a conductive metal oxide.

Through a fifteenth etching process, a portion of the preliminary third light emitting layer EL3-P, a portion of the preliminary third common electrode CE3-P, and a portion of the preliminary third inorganic encapsulation layer ENC13-P that does not overlap the third sacrificial protective layer EPL3 may be removed. Accordingly, the third light emitting layer EL3, the third common electrode CE3 on the third light emitting layer EL3, and the third first inorganic encapsulation layer ENC13 on the third common electrode CE3 may be formed in the third pixel area PX3. In an embodiment, for example, the fifteenth etching process may be a dry etching process or a wet etching process.

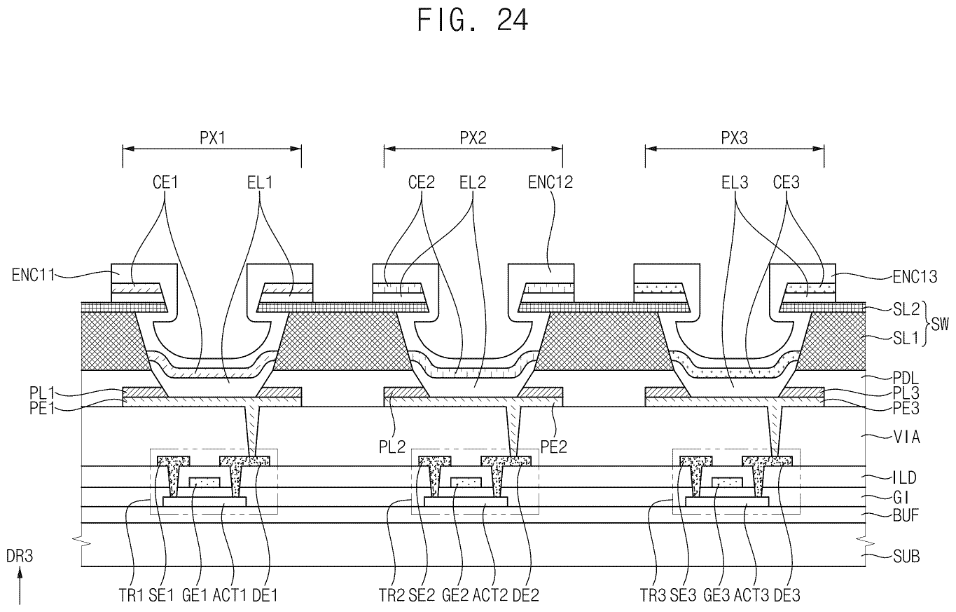

Referring further to FIG. 24, the first, second, and third sacrificial protective layers EPL1, EPL2, and EPL3 may be removed.

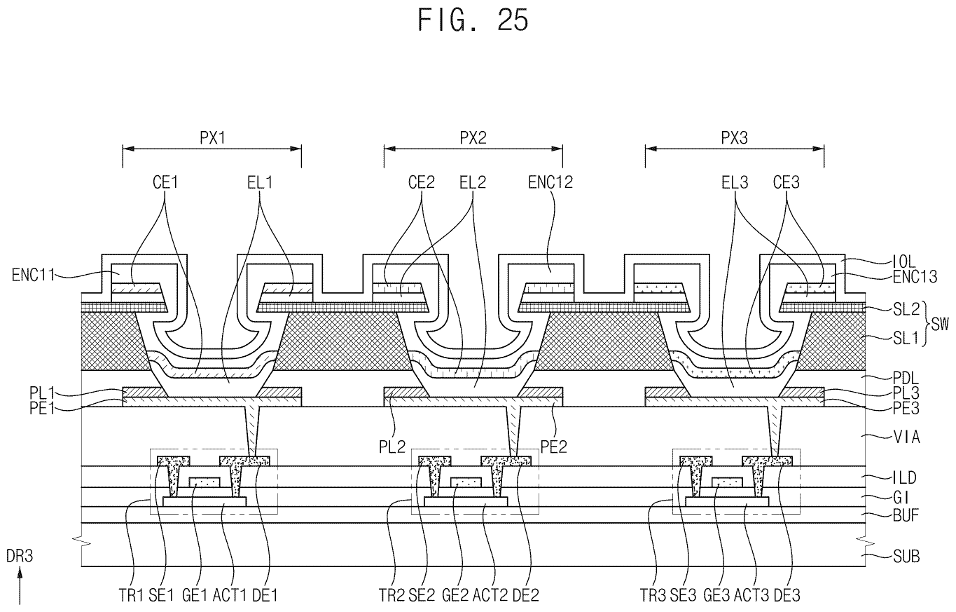

Referring further to FIG. 25, the inorganic insulating layer IOL may be formed entirely on the first first, second first, and third first inorganic encapsulation layers ENC11, ENC12, and ENC13. In an embodiment, for example, the inorganic insulating layer IOL may be formed using an inorganic material such as silicon oxide, silicon nitride, silicon oxynitride, or the like.

Referring back to FIG. 2, the organic encapsulation layer ENC2 may be entirely formed on the inorganic insulating layer IOL. In an embodiment, for example, the organic encapsulation layer ENC2 may be formed using a polymer cured material such as polyacrylate or the like.

The second inorganic encapsulation layer ENC3 may be entirely formed on the organic encapsulation layer ENC2. In an embodiment, for example, the second inorganic encapsulation layer ENC3 may be formed using an inorganic material such as silicon oxide, silicon nitride, silicon oxynitride, or the like.

Accordingly, the display device DD shown in FIGS. 2 and 3 may be manufactured.

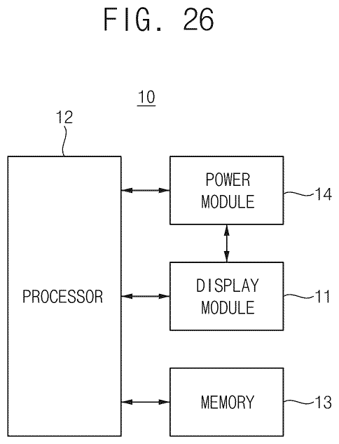

FIG. 26 is a block diagram showing an electronic device according to embodiments of the present disclosure.

Referring to FIG. 26, an electronic device 10 may include a display module 11, a processor 12, a memory 13, and a power module 14.

A display device according to embodiments (e.g., the display device DD of FIGS. 1 and 2) may be applied to various electronic devices 10. The electronic device 10 may include the display device described above, and may further include modules or devices with additional functions other than the display device.

The processor 12 may include at least one of a central processing unit (CPU), an application processor (AP), a graphic processing unit (GPU), a communication processor (CP), an image signal processor (ISP), and a controller. The processor 12 may control the display device.

The memory 15 may store data information necessary for the operation of the processor 12 or the display module 11. When the processor 12 executes the application stored in the memory 15, an image data signal and/or an input control signal may be transmitted to the display module 11, and the display module 11 may process the received signal and output image information through a display screen.

The power module 14 may include a power supply module, such as a power adapter or a battery device, and a power conversion module which converts the power supplied by the power supply module to generate power required for the operation of the electronic device 10.

At least one of each component of the electronic device 10 described above may be included in the display device according to the above-described embodiments. In addition, some of the individual modules functionally included in one module may be included in the display device, and other portions may be provided separately from the display device. For example, the display device may include the display module 11, and the processor 12, the memory 13, and the power module 14 may be provided in the form of other devices within the electronic device 10 other than the display device.

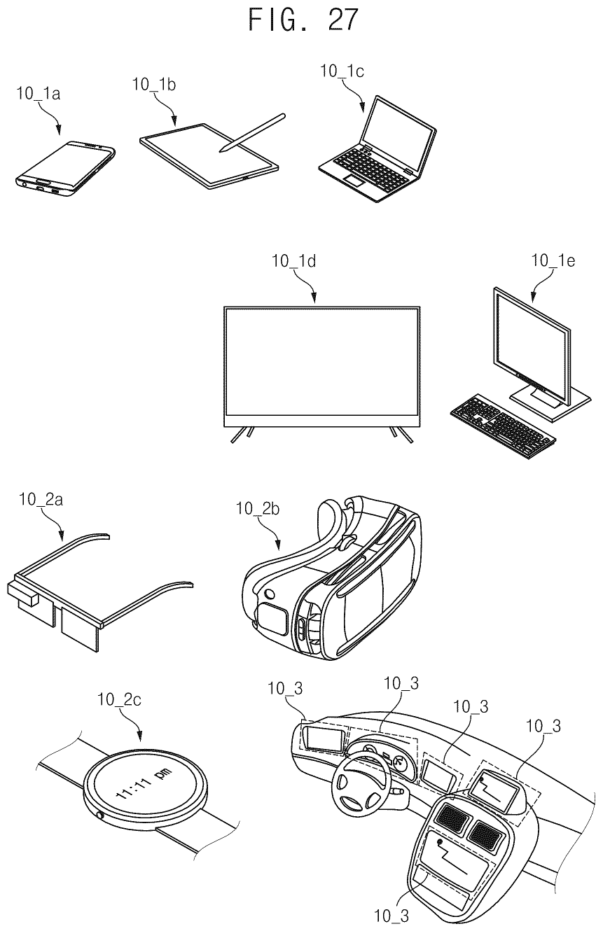

FIG. 27 are schematic diagrams showing an electronic device according to various embodiments.

Referring to FIG. 27, various electronic devices 10 to which display devices according to the embodiments (e.g., the display device DD of FIGS. 1 and 2) are applied may include not only image display electronic devices such as a smartphone 10_1a, a tablet PC 10_1b, a laptop 10_1c, a TV 10_1d, and a desktop monitor 10_1e, but also wearable electronic devices including display modules, such as smart glasses 10_2a, a head-mounted display 10_2b, and a smart watch 10_2c, automotive electronic devices 103 including display modules, such as a dashboard of a car, a center fascia, a Center Information Display (CID) disposed on a dashboard, and a room mirror display, or the like.

The invention should not be construed as being limited to the embodiments set forth herein. Rather, these embodiments are provided so that this disclosure will be thorough and complete and will fully convey the concept of the invention to those skilled in the art.

The disclosure can be applied to various devices including display devices. For example, the disclosure is applicable to various devices such as vehicles, ships and aircraft, portable communication devices, exhibition or information transmission devices, medical devices, or the like.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a pixel electrode disposed on a substrate;
a pixel defining layer disposed on the pixel electrode and defining a pixel opening exposing a least a portion of an upper surface of the pixel electrode;
a side wall disposed directly on the pixel defining layer and having an undercut structure;
a light emitting layer disposed on the side wall, disposed inside the pixel opening, and disconnected by the undercut structure;
a first inorganic encapsulation layer disposed on the light emitting layer and directly contact a side surface of the side wall;
an organic encapsulation layer disposed on the first inorganic encapsulation layer; and
a second inorganic encapsulation layer disposed on the organic encapsulation layer.

2. The display device of claim 1, wherein a surface area of the first inorganic encapsulation layer is different from a surface area of the second inorganic encapsulation layer.

3. The display device of claim 2, wherein the surface area of the first inorganic encapsulation layer is greater than the surface area of the second inorganic encapsulation layer.

4. The display device of claim 1, wherein the side wall includes:
a first sub-layer disposed on the pixel defining layer and including a conductive material; and
a second sub-layer disposed on the first sub-layer, including a conductive material or an inorganic material, and having a second side surface protruding more toward a center of the pixel opening than a first side surface of the first sub-layer in a plan view.

5. The display device of claim 4, wherein the first sub-layer includes aluminum (Al) and the second sub-layer includes titanium (Ti).

6. The display device of claim 4, wherein a first angle between a side surface of the pixel defining layer and a lower surface of the pixel defining layer is in a range from about 40 degrees to about 90 degrees.

7. The display device of claim 6, wherein a second angle between a side surface of the first sub-layer and a lower surface of the first sub-layer is different from the first angle.

8. The display device of claim 7, wherein the second angle is greater than the first angle.

9. The display device of claim 6, wherein a second angle between a side surface of the first sub-layer and a lower surface of the first sub-layer is in a range from about 70 degrees to about 90 degrees.

10. The display device of claim 4, wherein a thickness of a portion of the first inorganic encapsulation layer contacting a lower surface of a protruding portion of the second sub-layer is less than about 0.3 micrometer.

11. The display device of claim 4, wherein a height of the first sub-layer is in a range from about 1 to about 2 times a length of a protruding portion of the second sub-layer in a horizontal direction.

12. The display device of claim 1, wherein an average thickness of the first first inorganic encapsulation layer is different from a thickness of the second inorganic encapsulation layer.

13. The display device of claim 1, further comprising:
a common electrode disposed between the light emitting layer and the first first inorganic encapsulation layer, and disconnected by the undercut structure.

14. The display device of claim 13, wherein the common electrode directly contacts an upper surface of the light emitting layer and at least a portion of the side surface of the side wall.

15. The display device of claim 1, further comprising:
a pixel protective layer disposed directly on the pixel electrode, exposing at least a portion of the pixel electrode, and including a conductive metal oxide.

16. The display device of claim 1, wherein the pixel defining layer includes an inorganic material.

17. An electronic device comprising:
a display device; and
a processor which controls the display device,
wherein the display device includes:
a pixel electrode disposed on a substrate;
a pixel defining layer disposed on the pixel electrode and defining a pixel opening exposing a least a portion of an upper surface of the pixel electrode;
a side wall disposed directly on the pixel defining layer and having an undercut structure;
a light emitting layer disposed on the side wall, disposed inside the pixel opening, and disconnected by the undercut structure;
a first inorganic encapsulation layer disposed on the light emitting layer and directly contact a side surface of the side wall;
an organic encapsulation layer disposed on the first inorganic encapsulation layer; and
a second inorganic encapsulation layer disposed on the organic encapsulation layer.

18. The electronic device of claim 17, wherein the surface area of the first inorganic encapsulation layer is greater than the surface area of the second inorganic encapsulation layer.

19. The electronic device of claim 17, wherein the side wall includes:
a first sub-layer disposed on the pixel defining layer and including a conductive material; and
a second sub-layer disposed on the first sub-layer, including a conductive material or an inorganic material, and having a second side surface protruding more toward a center of the pixel opening than a first side surface of the first sub-layer in a plan view.

20. The display device of claim 19, wherein a first angle between a side surface of the pixel defining layer and a lower surface of the pixel defining layer is in a range from about 40 degrees to about 90 degrees, and
a second angle between a side surface of the first sub-layer and a lower surface of the first sub-layer is in a range from about 70 degrees to about 90 degrees.
